(19) United States
(12) Patent Application Publication
(10) Pub. No.: US 2023/0163122 A1
(43) Pub. Date: May 25, 2023

(54) RC-IGBT

(71) Applicant: Mitsubishi Electric Corporation, Tokyo (JP)

(72) Inventors: Shinya SONEDA, Tokyo (JP); Koichi NISHI, Tokyo (JP); Kazuya KONISHI, Tokyo (JP)

(73) Assignee: Mitsubishi Electric Corporation, Tokyo (JP)

(21) Appl. No.: 17/933,677

(22) Filed: Sep. 20, 2022

(30) Foreign Application Priority Data
Nov. 24, 2021 (JP) 2021-190463

(51) Int. Cl. H01L 27/06; H01L 29/40; H01L 29/739

(52) U.S. Cl. CPC H01L 27/0664; H01L 29/407; H01L 29/7397

(57) ABSTRACT

An RC-IGBT includes a plurality of gate electrodes provided in a plurality of gate trenches, a plurality of dummy gate electrodes provided in a plurality of dummy trenches and having upper surfaces located below upper surfaces of the plurality of gate electrodes, an interlayer insulating film provided on an upper surface of a semiconductor substrate and having a first contact hole in which at least one side wall of each dummy trench is exposed above a corresponding dummy gate electrode, and an emitter electrode provided on the interlayer insulating film and in the first contact hole and electrically connected to a base layer on the side wall of each dummy trench exposed to the first contact hole. At least one dummy trench is disposed between two gate trenches.

### BACKGROUND OF THE INVENTION

### Field of the Invention

The present disclosure relates to an RC-IGBT.

### DESCRIPTION OF THE BACKGROUND ART

A reverse conducting insulated gate bipolar transistor (RC-IGBT) has an IGBT region and a diode region within a single semiconductor substrate. In the RC-IGBT described in Japanese Patent Application Laid-Open No. 2010-171326, a trench contact reaching an inside of a p-type base layer is provided in a mesa region between adjacent active trench gates so that contact with the p-type base layer is established at a position deeper than a substrate surface, and thereby latch-up tolerance of the IGBT is improved.

Since the RC-IGBT described in Japanese Patent Application Laid-Open No. 2010-171326 has a trench contact in the mesa region, it is necessary to secure a width for the trench contact, and therefore an interval between the trench gates, that is, a mesa width cannot be sufficiently narrowed. Therefore, there is a problem that it is difficult to obtain a carrier accumulation effect obtained by narrowing the mesa width, and an on-voltage cannot be sufficiently reduced.

### SUMMARY

The present disclosure has been made to solve the above problem, and an object of the present disclosure is to reduce an on-voltage while increasing latch-up tolerance in an RC-IGBT.

An RC-IGBT of the present disclosure includes a semiconductor substrate. The semiconductor substrate has an IGBT region and a diode region. The semiconductor substrate includes an n type drift layer, a p type base layer, and an n type source layer. The drift layer is provided in the IGBT region and the diode region. The base layer is provided on the drift layer in the IGBT region. The source layer is provided on the base layer in the IGBT region, constitutes an upper surface of the semiconductor substrate, and has a higher n type impurity concentration than the drift layer. A plurality of gate trenches and a plurality of dummy trenches are provided in the semiconductor substrate. The plurality of gate trenches and the plurality of dummy trenches penetrate the base layer from the upper surface of the semiconductor substrate and reach the drift layer in the IGBT region, and a longitudinal direction thereof is a first direction. The RC-IGBT further includes a plurality of gate electrodes, a plurality of dummy gate electrodes, an interlayer insulating film, and an emitter electrode. The plurality of gate electrodes are provided in the plurality of gate trenches with a gate insulating film interposed therebetween. The plurality of dummy gate electrodes are provided in the plurality of dummy trenches with a dummy gate insulating film interposed therebetween, and have upper surfaces located below upper surfaces of the plurality of gate electrodes. The interlayer insulating film is provided on the upper surface of the semiconductor substrate in the IGBT region, and has a first contact hole in which at least one side wall of each dummy trench is exposed above a corresponding one of the dummy gate electrodes. The emitter electrode is provided on the interlayer insulating film and in the first contact hole in the IGBT region, and is electrically connected to the base layer on the side wall of each dummy trench exposed to the first contact hole. At least one dummy trench included in the plurality of dummy trenches is disposed between two gate trenches included in the plurality of gate trenches.

The RC-IGBT of the present disclosure has a hole discharge path on the side wall of the dummy trench, and a distance of the hole discharge path is shortened accordingly. This reduces pinch resistance, thereby improving latch-up tolerance. Therefore, it is possible to reduce an on-voltage by narrowing an active mesa width while increasing the latch-up tolerance.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view of a stripe-type RC-IGBT;

FIG. 2 is a plan view of an island-type RC-IGBT;

FIG. 3 is a partially enlarged plan view of an IGBT region in an RC-IGBT according to a first, fourth, or ninth preferred embodiment;

FIG. 4 is a cross-sectional view of the IGBT region in the RC-IGBT according to the first preferred embodiment taken along line A-A in FIG. 3;

FIG. 5 is a cross-sectional view of the IGBT region in the RC-IGBT according to the first preferred embodiment taken along line B-B in FIG. 3;

FIG. 6 is a partially enlarged plan view of a diode region in the RC-IGBT according to the first preferred embodiment;

FIG. 7 is a cross-sectional view of the IGBT region in the RC-IGBT according to the first preferred embodiment taken along line L-L in FIG. 6;

FIG. 8 is a cross-sectional view of the IGBT region in the RC-IGBT according to the first preferred embodiment taken along line M-M in FIG. 6;

FIG. 9 is a partially enlarged plan view of an IGBT region in an RC-IGBT according to a second preferred embodiment;

FIG. 10 is a cross-sectional view of the IGBT region in the RC-IGBT according to the second preferred embodiment taken along line C-C in FIG. 9;

FIG. 11 is a partially enlarged plan view of an IGBT region in an RC-IGBT according to a third preferred embodiment;

FIG. 12 is a cross-sectional view of the IGBT region in the RC-IGBT according to the third preferred embodiment taken along line D-D in FIG. 11;

FIG. 13 is a cross-sectional view of an IGBT region in an RC-IGBT according to a fourth preferred embodiment taken along line B-B in FIG. 3;

FIG. 14 is a partially enlarged plan view of an IGBT region in an RC-IGBT according to a fifth preferred embodiment;

FIG. 15 is a cross-sectional view of the IGBT region in the RC-IGBT according to the fifth preferred embodiment taken along line H-H in FIG. 14;

FIG. 16 is a partially enlarged plan view of an IGBT region in an RC-IGBT according to a sixth preferred embodiment;

FIG. 17 is a cross-sectional view of the IGBT region in the RC-IGBT according to the sixth preferred embodiment taken along line I-I in FIG. 16;

FIG. 18 is a cross-sectional view of the IGBT region in the RC-IGBT according to the sixth preferred embodiment taken along line J-J in FIG. 16;

FIG. 19 is a partially enlarged plan view of an IGBT region in an RC-IGBT according to a seventh preferred embodiment;

FIG. 20 is a cross-sectional view of the IGBT region in the RC-IGBT according to the seventh preferred embodiment taken along line K-K in FIG. 19;

FIG. 21 is a cross-sectional view of an IGBT region in an RC-IGBT according to a modification of the seventh preferred embodiment taken along line K-K in FIG. 19;

FIG. 22 is a partially enlarged plan view of an IGBT region in an RC-IGBT according to an eighth preferred embodiment;

FIG. 23 is a cross-sectional view of the IGBT region in the RC-IGBT according to the eighth preferred embodiment taken along line A-A in FIG. 22; and

FIG. 24 is a cross-sectional view of an IGBT region in an RC-IGBT according to a ninth preferred embodiment taken along line A-A in FIG. 3.

### DESCRIPTION OF THF PREFERRED EMBODIMENTS

Hereinafter, preferred embodiments will be described with reference to the accompanying drawings. Note that the drawings are schematically illustrated, and mutual relationships between sizes and positions of images illustrated in different drawings are not necessarily accurate, and can be appropriately changed. In addition, in the following description, similar constituent elements are given identical reference signs, and names and functions thereof are also similar. Therefore, detailed description thereof may be omitted.

In addition, in the following description, terms meaning specific positions and directions such as “upper”, “lower”, “side”, “bottom”, “front”, and “back” may be used, but these terms are used for convenience to facilitate understanding of the contents of the embodiment, and do not limit directions during actual implementation.

Regarding a conductivity type of a semiconductor layer, an n− type indicates a lower n− type impurity concentration than an n type, and an n+ type indicates a higher n− type impurity concentration than the n type. Furthermore, a p− type indicates a lower p− type impurity concentration than a p type, and a p+ type indicates a higher p-type impurity concentration than the p type.

### A. Background Art

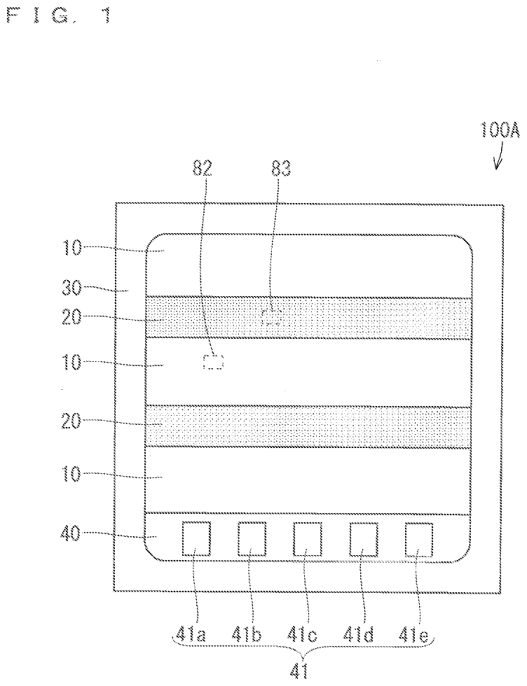

FIG. 1 is a plan view of a stripe-type RC-IGBT 100A. As illustrated in FIG. 1, the RC-IGBT 100A includes an IGBT region 10 and a diode region 20 within a single semiconductor substrate. The IGBT region 10 and the diode region 20 extend from one end side to the other end side of the RC-IGBT 100A, and are alternately provided in a stripe shape in a direction orthogonal to a direction in which the IGBT region 10 and the diode region 20 extend. Therefore, the RC-IGBT 100A is called a stripe type.

FIG. 1 illustrates three IGBT regions 10 and two diode regions 20, and illustrates a configuration in which each diode region 20 is sandwiched between two IGBT regions 10. However, the number of the IGBT regions 10 and the number of diode regions 20 in the RC-IGBT 100A are not limited to this. The number of IGBT regions 10 may be 3 or more or may be less than 3, and the number of diode regions 20 may be 2 or more or may be less than 2. In FIG. 1, the IGBT regions 10 may be interchanged with the diode regions 20 so that each IGBT region 10 is sandwiched between two diode regions 20. It is also possible to employ a configuration in which a single IGBT region 10 and a single diode region 20 are provided adjacent to each other.

Furthermore, the RC-IGBT 100A includes a termination region 30 and a pad region 40. In FIG. 1, the pad region 40 is provided adjacent to the IGBT region 10 on a lower side of the paper on which FIG. 1 is drawn. The pad region 40 is a region where a control pad 41 for controlling the RC-IGBT 100A is provided.

The IGBT regions 10 and the diode regions 20 are collectively referred to as a cell region. The termination region 30 is provided around a region combining the cell region and the pad region 40 in order to maintain a withstand voltage of the RC-IGBT 100A.

A known withstand voltage holding structure can be appropriately selected and provided in the termination region 30. As the withstand voltage holding structure, for example, a field limiting ring (FLR) in which the cell region is surrounded by a p type termination well layer of a p type semiconductor or a variation of lateral doping (VLLD) in which the cell region is surrounded by a p type well layer having a concentration gradient may be provided on a first main surface side, which is an upper surface side of the RC-IGBT 100A. The number of ring-shaped p type termination well layers used for the FLR or a concentration distribution used for the VLD may be appropriately selected according to withstand voltage design of the RC-IGBT 100A. Furthermore, a p type termination well layer may be provided almost all over the pad region 40 or an IGBT cell or a diode cell may be provided in the pad region 40.

The control pad 41 is, for example, a current sense pad 41a, a Kelvin emitter pad 41b, a gate pad 41c, or temperature sense diode pads 41d and 41e. The current sense pad 41a is a control pad for detecting a current flowing through the cell region of the RC-1013T 100A. The current sense pad 41a is electrically connected to an IGBT cell or a diode cell of the cell region so that when a current flows in the cell region of the RC-IGBT 100A, a current that is several times to several million times smaller than the current flowing in the entire cell region flows.

The Kelvin emitter pad 41b and the gate pad 41c are control pads to which a gate drive voltage for controlling on/off of the RC-IGBT 100A is applied. The Kelvin emitter pad 41b is electrically connected to a p type base layer of the IGBT cell, and the gate pad 41c is electrically connected to a gate trench electrode of the IGBT cell. The Kelvin emitter pad 41b and the p type base layer may be electrically connected with a p+ type contact layer interposed therebetween.

The temperature sense diode pads 41d and 41e are control pads electrically connected to an anode and a cathode of a temperature sense diode provided in the RC-IGBT 100A. The temperature sense diode pads 41d and 41 measure a temperature of the RC-IGBT 100A by measuring a voltage between the anode and the cathode of the temperature sense diode (not illustrated) provided in the cell region or the pad region 40.

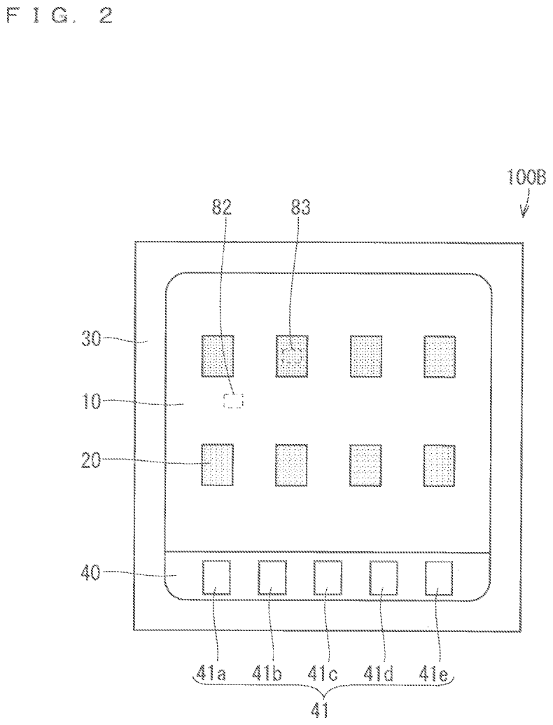

FIG. 2 is a plan view of an island-type RC-IGBT 100B. The RC-IGBT 100B differs from the stripe-type RC-IGBT 100A only in arrangement of the IGBT region 10 and the diode region 20 in the cell region.

In the RC-IGBT 100B, a plurality of diode regions 20 are arranged in an up-down direction and a left-right direction of the paper on which FIG. 2 is drawn. These diode regions 20 are surrounded by the IGBT region 10. That is, the plurality of diode regions 20 are provided like islands in the IGBT region 10. Therefore, the RC-IGBT 100B is called an island type.

In FIG. 2, eight diode regions 20 are arranged in a matrix of four columns in the left-right direction of the paper and two rows in the up-down direction of the paper. However, the number and arrangement of the diode regions 20 are not limited to this. It is only necessary that one or a plurality of diode regions 20 are interspersed in the IGBT region 10 and each diode region 20 is surrounded by the IGBT region 10.

In FIG. 2, the pad region 40 is provided adjacent to a lower side of the IGBT region 10 on the paper on which FIG. 2 is drawn. The configurations of the pad region 40 and the termination region 30 in the RC-IGBT 100B are similar to those in the RC-IGBT 100A.

### B. First Preferred Embodiment

### B-.1 IGBT Region

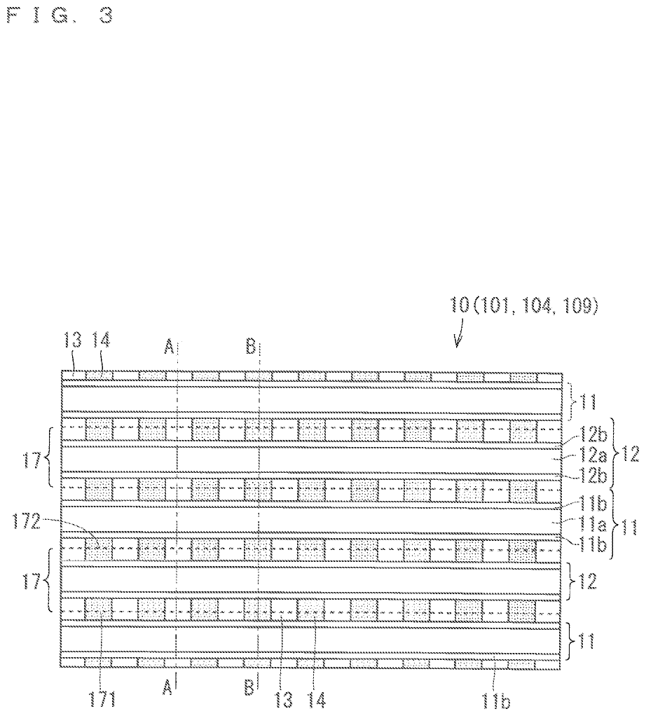

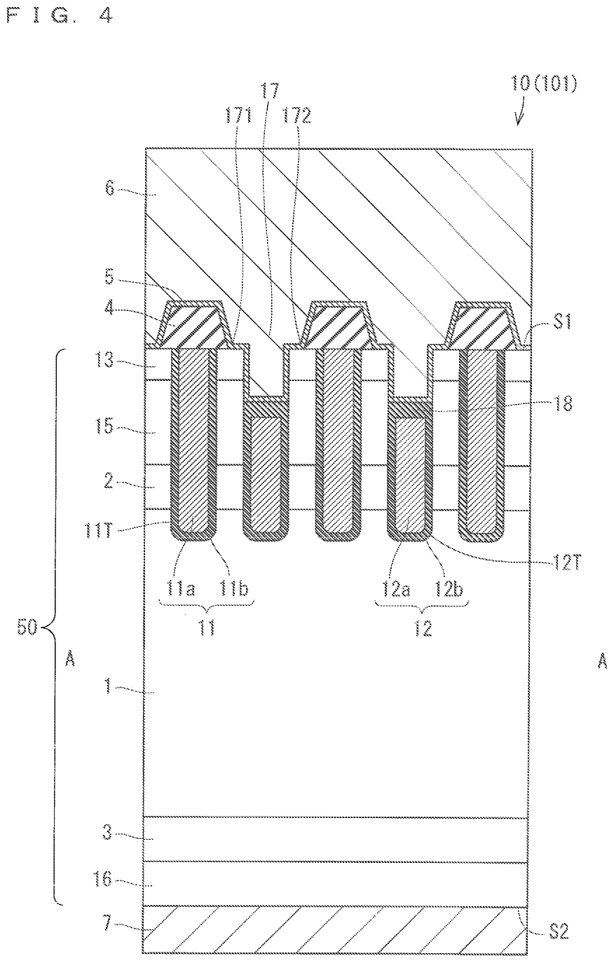

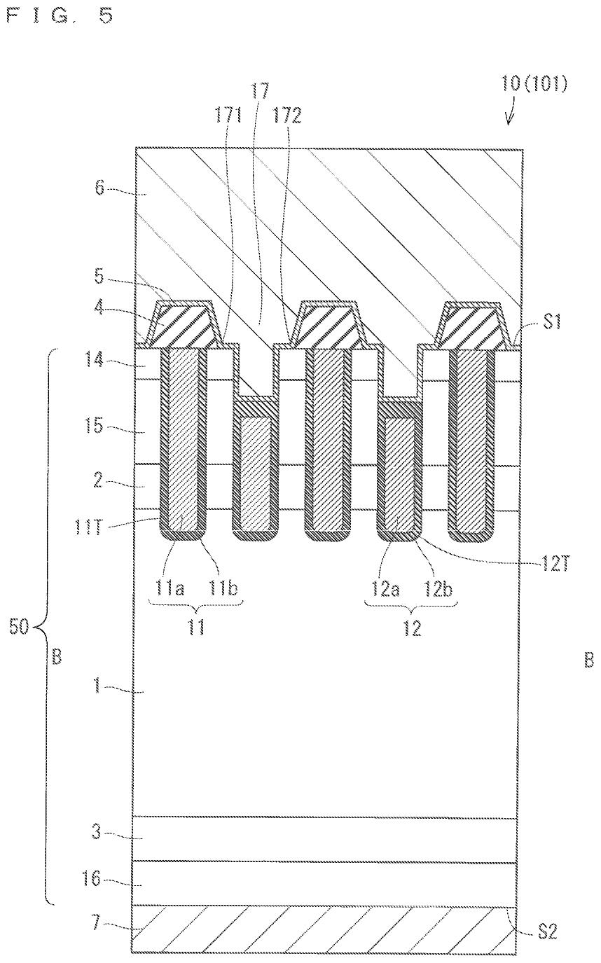

FIG. 3 is a partially enlarged plan view illustrating a configuration of an IGBT region 10 in an RC-IGBT 101 according to a first preferred embodiment. Either the RC-IGBT 101A illustrated in FIG. 1 or the RC-IGBT 100B illustrated in FIG. 2 is applied as the RC-IGBT 101 according to the first preferred embodiment. FIG. 3 is an enlarged view of a region surrounded by the broken line 82 in the RC-IGBT 110A illustrated in FIG. 1 or the RC-IGBT 100B illustrated in FIG. 2. FIG. 4 is a cross-sectional view of the IGBT region 10 taken along dashed line A-A in FIG. 3. FIG. 5 is a cross-sectional view of the IGBT region 10 taken along dashed line B-B in FIG. 3.

As illustrated in FIG. 3, the RC-IGBT 101 includes an active trench gate 11 and a dummy trench gate 12 provided in a stripe shape in the IGBT region 10. The active trench gate 11 and the dummy trench gate 12 extend in a longitudinal direction of the IGBT region 10. In other words, the longitudinal direction of the IGBT region 10 coincides with a longitudinal direction of the active trench gate 11 and the dummy trench gate 12. Hereinafter, the longitudinal direction of the active trench gate 11 and the dummy trench gate 12 is also referred to as a first direction. In the case of the island-type RC-IGBT 100B, there is no distinction between a longitudinal direction and a lateral direction of the IGBT region 10, but either the left-right direction or the up-down direction of the paper on which FIG. 2 is drawn may be set as the longitudinal direction of the active trench gate 11 and the dummy trench gate 12.

As illustrated in FIGS. 3 to 5, the active trench gate 11 includes a gate insulating film 11b and a gate electrode 11a. A gate trench 11T is provided in a semiconductor substrate 50. The gate insulating film 11b is provided on a side wall and a bottom surface of the gate trench 11T. The gate electrode 11a is provided in the gate trench 11T with the gate insulating film 11b interposed therebetween. The dummy trench gate 12 includes a dummy gate insulating film 12b and a dummy gate electrode 12a. A gate trench 12T is provided in the semiconductor substrate 50. The dummy gate insulating film 12b is provided on a side wall and a bottom surface of the dummy trench 12T. The dummy gate electrode 12a is provided in the dummy trench 12T with the dummy gate insulating film 12b interposed therebetween. The gate electrode 11a is electrically connected to the gate pad 41c. The dummy gate electrode 12a is electrically connected to the gate electrode 11a.

As illustrated in FIG. 3, the RC-IGBT 101 includes an n+ type source layer 13 and a p+ type contact layer 14 in the IGBT region 10. The n+ type source layer 13 is provided in contact with the gate insulating film 11b on both sides in the width direction of the active trench gate 11. The n+ type source layer 13 is a semiconductor layer containing, for example, arsenic or phosphorus as an n type impurity. A concentration of the n type impurity in the n+ type source layer 13 is 1.0×10⁷/cm³ or more and 1.0×10²⁰/cm³ or less. The n+ type source layer 13 and the p+ type contact layer 14 are alternately provided in the direction in which the active trench gate 11 extends. The p+ type contact layer 14 is a semiconductor layer containing, for example, boron or aluminum as a p type impurity. A concentration of the p type impurity in the p+ type contact layer 14 is 1.0×10¹⁵/cm³ or more and 1.0×10²⁰/cm³ or less. Although the active trench gate 11 and the dummy trench gate 12 are alternately arranged in FIG. 3, the arrangement of the active trench gate 11 and the dummy trench gate 12 is not limited to this. Two or more dummy trench gates 12 may be disposed between two active trench gates 11. In this case, the p+ type contact layer 14 is also provided between two adjacent dummy trench gates 12. Note that the n+ type source layer 13 is sometimes also referred to as an n+ type emitter layer.

An interval between the active trench gate 11 and the dummy trench gate 12 is referred to as an active mesa width. The active mesa width is, for example, 0.2 μm or more and 1.2 μm or less. A depth of the active trench gate 11 is, for example, 3 μm or more and 7 μm or less. A depth of the dummy trench gate 12 is, for example, 3 μm or more and 7 μm or less, and need not be the same as the depth of the active trench gate 11.

As illustrated in FIGS. 4 and 5, the RC-IGBT 101 includes an n− type drift layer 1, an n type carrier accumulation layer 2, a p type base layer 15, an n type buffer layer 3, and a p type collector layer 16 in the IGBT region 10. As illustrated in FIG. 4, the RC-IGBT 101 includes the n+ type source layer 13 in the IGBT region 10, and as illustrated in FIG. 5, the RC-IGBT 101 includes the p+ type contact layer 14 in the IGBT region 10. The n+ type source layer 13 provided on a first main surface S1 side of the semiconductor substrate 50 in contact with the active trench gate 11 in FIG. 4 is not seen in FIG. 5. Instead, the p+ type contact layer 14 is illustrated in FIG. 5. That is, as illustrated in FIG. 3, the n+ type source layer 13 is intermittently disposed on the first main surface S1 side of the p type base layer 15 along the direction in which the active trench gate 11 extends. With this configuration, current carrying capability can be adjusted according to an arrangement area of the n+ type source layer 13.

The n− type drift layer 1 is made of the semiconductor substrate 50. The n− type drift layer 1 is a semiconductor layer containing, for example, arsenic or phosphorus as an n type impurity. A concentration of the n type impurity in the n− type drift layer 1 is 1.0×10¹²/cm³ or more and 1.0×10¹⁵/cm³ or less. The semiconductor substrate 50 corresponds to a range from the n+ type source layer 13 to the p type collector layer 16 in FIG. 4, and corresponds to a range from the p+ type contact layer 14 to the p type collector layer 16 in FIG. 5. An upper end of the n+ type source layer 13 on the paper on which FIG. 4 is drawn or an upper end of the p+ type contact layer 14 on the paper on which FIG. 5 is drawn is referred to as a first main surface S1 of the semiconductor substrate 50, and a lower end of the p type collector layer 16 on the paper on which FIGS. 4 and 5 are drawn is referred to as a second main surface S2 of the semiconductor substrate 50. The first main surface S1 of the semiconductor substrate 50 is a main surface on an upper surface side of the RC-IGBT 101, and the second main surface 82 of the semiconductor substrate 50 is a main surface on a lower surface side of the RC-IGBT 101. The RC-IGBT 101 has the n− type drift layer 1 between the first main surface S1 and the second main surface S2 facing the first main surface S1 in the IGBT region 10 that is a cell region.

The n type carrier accumulation layer 2 is provided on a first main surface S1 side of the n− type drift layer 1. The n type carrier accumulation layer 2 has a higher concentration of n type impurity than the n− type drift layer 1. The n type carrier accumulation layer 2 is a semiconductor layer containing, for example, arsenic or phosphorus as an n type impurity. A concentration of the n type impurity in the n type carrier accumulation layer 2 is 1.0×10¹³/cm³ or more and 1.0×10⁷/cm³ or less. The RC-IGBT 101 may be configured not to include the n type carrier accumulation layer 2, and may be configured such that the n− type drift layer 1 is also provided in the region where the n type carrier accumulation layer 2 is provided illustrated in FIGS. 4 and 5. By providing the n type carrier accumulation layer 2, a loss of a current flowing in the IGBT region 10 can be reduced. The n− type drift layer 1 and the n type carrier accumulation layer 2 may be collectively referred to as a drift layer. The n type carrier accumulation layer 2 is formed by ion-implanting the n type impurity into the semiconductor substrate 50 constituting the n− type drift layer 1 and then diffusing the implanted n type impurity in the semiconductor substrate 50 that is the n− type drift layer 1 by annealing.

The p type base layer 15 is provided on a first main surface S1 side of the n type carrier accumulation layer 2. The p type base layer 15 is a semiconductor layer containing, for example, boron or aluminum as a p type impurity. A concentration of the p type impurity in the p type base layer 15 is 1.0×10¹²/cm³ or more and 1.0×10¹⁹/cm³ or less. The p type base layer 15 is in contact with the gate insulating film 11b of the active trench gate 11. On a first main surface S1 side of the p type base layer 15, the n+ type source layer 13 and the p+ type contact layer 14 are provided in contact with the gate insulating film 11b of the active trench gate 11. Upper surfaces of the n+ type source layer 13 and the p+ type contact layer 14 constitute the first main surface S1 of the semiconductor substrate 50. Note that the p+ type contact layer 14 is a region having a higher p type impurity concentration than the p type base layer 15. In a case where the p+ type contact layer 14 and the p type base layer 15 need not be distinguished from each other, the p+ type contact layer 14 and the p type base layer 15 may be collectively referred to as a p type base layer.

The n type buffer layer 3 is provided on a second main surface S2 side of the n− type drift layer 1. The n type buffer layer 3 has a higher concentration of an n type impurity than the n− type drift layer 1. The n type buffer layer 3 is provided to suppress punch-through of a depletion layer extending from the p type base layer 15 toward the second main surface S2 when the RC-IGBT 101 is in an off state. The n type impurity of the n type buffer layer 3 is, for example, one or both of phosphorus (P) and proton (H+). A concentration of the n type impurity in the n type buffer layer 3 is 1.0×10¹²/cm³ or more and 1.0×10¹⁸/cm³ or less. The RC-IGBT 101 may be configured not to include the n type buffer layer 3, and may be configured such that the n− type drift layer 1 is also provided in the region where the n type buffer layer 3 is provided illustrated in FIGS. 4 and 5. The n− type drift layer 1, the n type carrier accumulation layer 2, and the n type buffer layer 3 may be collectively referred to as a drift layer.

The p type collector layer 16 is provided on a second main surface S2 side of the n type buffer layer 3. That is, the p type collector layer 16 is provided between the n− type drift layer 1 and the second main surface S2. The p type collector layer 16 is a semiconductor layer containing, for example, boron or aluminum as a p type impurity. A concentration of the p type impurity in the p type collector layer 16 is 1.0×10¹⁶/cm³ or more and 1.0×10²⁰/cm³ or less. A lower surface of the p type collector layer 16 constitutes the second main surface S2 of the semiconductor substrate 50. The p type collector layer 16 is provided not only in the IGBT region 10 but also in the termination region 30, and a portion of the p type collector layer 16 provided in the termination region constitutes a p type termination collector layer. Furthermore, the p type collector layer 16 may be provided so that a part thereof protrudes from the IGBT region 10 to the diode region 20.

As illustrated in FIG. 4, in the IGBT region 10 of the RC-IGBT 101, the gate trench 11T and the dummy trench 12T that penetrate the p type base layer 15 from the first main surface S1 of the semiconductor substrate 50 and reach the n− type drift layer 1 are provided. The active trench gate 11 is configured such that the gate electrode 11a is provided in the gate trench 11T with the gate insulating film 11b interposed therebetween. The gate electrode 11a faces the n− type drift layer 1 with the gate insulating film 11b interposed therebetween. The dummy trench gate 12 is configured such that the dummy gate electrode 12a is provided in the dummy trench 12T with the dummy gate insulating film 12b interposed therebetween. The dummy gate electrode 12a faces the n− type drift layer 1 with the dummy gate insulating film 12b interposed therebetween. The gate insulating film 11b of the active trench gate 11 is in contact with the p type base layer 15 and the n+ type source layer 13. When a gate drive voltage is applied to the gate electrode 11a, a channel is formed in the p type base layer 15 that is in contact with the gate insulating film 11b of the active trench gate 11.

As illustrated in FIG. 4, since an upper end of the dummy gate electrode 12a is below an upper end of the gate electrode 11a, an emitter electrode 6 can be brought into contact with a side wall of the dummy trench 12T above the dummy gate electrode 12a. A separation insulating film 18 is provided between the dummy gate electrode 12a and the emitter electrode 6, and thereby the dummy gate electrode 12a and the emitter electrode 6 are electrically separated. Since the emitter electrode 6 is in contact with the side wall of the dummy trench 12T, a hole discharge path can be provided at a position deeper than the first main surface S1 of the semiconductor substrate 50. Normally, when a current is cut off, a hole reaching below the n+ type source layer 13 is discharged to the emitter electrode 6 via the p+ type contact layer 14 while bypassing the n+ type source layer 13. A resistance component generated in such a detour path is referred to as pinch resistance. When a voltage drop generated in the pinch resistance increases, a phenomenon called latch-up in which a parasitic thyristor is turned on occurs. As a result, a current cannot be cut off, leading to breakdown. A current value that can be cut off without causing a latch-up phenomenon is referred to as a latch-up tolerance. In the RC-IGBT 101, the hole discharge path is provided on the side wall of the dummy trench 12T, and a distance of the hole discharge path is shortened accordingly. This reduces the pinch resistance, thereby improving the latch-up tolerance. When the active mesa width is narrowed, a carrier accumulation effect is improved and an on-voltage is reduced. This improves a conduction loss, but at the same time, increases a current density in the active mesa, thereby lowering the latch-up tolerance. However, according to the RC-IGBT 101, since the latch-up tolerance is improved as described above, it is possible to realize loss improvement due to a narrow active mesa while maintaining the latch-up tolerance.

According to the configuration of the RC-IGBT 101, a contact opening width wider than the active mesa width can be provided, and therefore the configuration can be realized without using a high-cost microfabrication process such as a W plug.

The dummy gate electrode 12a is connected to the gate electrode 11a by wiring on a cross section different from the cross section illustrated in FIG. 4. Therefore, when a gate drive voltage is applied to the gate electrode 11a, the same voltage is also applied to the dummy gate electrode 12a. Accordingly, when a gate drive voltage is applied to the gate electrode 11a, an accumulate layer is formed in a region of the n− type drift layer 1 and the n type carrier accumulation layer 2 that is in contact with the dummy gate insulating film 12b. This accumulate layer has an effect equivalent to a carrier accumulation effect of increasing a carrier density on an emitter side during energization. Therefore, this leads to a reduction in loss.

As illustrated in FIG. 4, the p type base layer 15 adjacent to the dummy trench gate 12 is in contact with the emitter electrode 6 on both side walls of the dummy trench 12T, and thus does not float. If the dummy gate electrode 12a connected to the gate electrode 11a or the p type base layer 15 disposed beside the gate electrode 11a is floating, a gate current is accelerated by carriers accumulated in the floating p type base layer 15 during turn-on, and controllability of the gate is deteriorated. However, in the RC-IGBT 101, the p type base layer 15 is not floating, and therefore the above problem can be avoided.

As illustrated in FIGS. 4 and 5, an upper surface of the separation insulating film 18 is located below a lower surface of the n+ type source layer 13. With this configuration, a hole discharge path is provided at a position deeper than the n+ type source layer 13, and therefore the latch-up tolerance is further improved.

The n+ type source layer 13 may be configured not to be in contact with the side wall of the dummy trench 12T. However, according to the configuration of the RC-IGBT 101, the hole discharge path is formed at a deep position, and therefore the latch-up tolerance can be maintained even if the n+ type source layer 13 is exposed to the side wall of the dummy trench 12T as illustrated in FIG. 4. That is, the n+ type source layer 13 may be in contact with the side wall of the dummy trench 12T and exposed from a first contact hole 17, and the emitter electrode 6 may be electrically connected to the n+ type source layer 13 exposed from the first contact hole 17. This enlarges a contact area between the n+ type source layer 13 and the emitter electrode 6 and thereby reduces contact resistance.

The separation insulating film 18 serves as a capacitance between the dummy gate electrode 12a and the emitter electrode 6. The smaller the capacitance becomes, the more easily the IGBT is driven, which is desirable. By making the separation insulating film 18 thicker than the gate insulating film 11b, capacitance formed in the dummy trench gate 12 can be reduced, and influence on driving of the IGBT can be reduced.

Since the dummy gate insulating film 12b also serves as a capacitance of the gate, it is more desirable that the capacitance is smaller. Therefore, by making the dummy gate insulating film 12b thicker than the gate insulating film 11b, the gate capacitance generated in the dummy trench gate 12 can be reduced. Unlike the gate insulating film 11b, the dummy gate insulating film 12b does not affect important electrical characteristics such as a threshold voltage of a transistor portion, and therefore a thickness thereof can be easily adjusted.

The dummy gate electrode 12a may be connected to one or a plurality of second gate pads different from a first gate pad to which the gate electrode 11a is connected. With the configuration, the gate electrode 11a and the dummy gate electrode 12a can be independently driven. For example, by lowering the gate drive voltage of the dummy gate electrode 12a earlier than the gate electrode 11a at a time of switching off, the accumulate layer disappears first, and a carrier density in the n− type drift layer 1 can be lowered. As a result, the conduction loss can be reduced at a high carrier density during energization, and a switching speed can be increased by reducing a carrier density and a switching loss can also be reduced during switching.

As illustrated in FIGS. 4 and 5, the RC-IGBT 101 includes an interlayer insulating film 4, a barrier metal 5, the emitter electrode 6, and a collector electrode 7 in the IGBT region 10. The interlayer insulating film 4 is provided on the first main surface S1 of the semiconductor substrate 50 and covers the gate electrode 11a. As illustrated in FIG. 3, the first contact hole 17 of the interlayer insulating film 4 extends in the longitudinal direction of the active trench gate 11 and the dummy trench gate 12. Furthermore, as illustrated in FIGS. 3 to 5, one end 171 and the other end 172 of the first contact hole 17 are on the n+ type source layer 13 or the p+ type contact layer 14 between the dummy trench gate 12 and the active trench gate 11 adjacent thereto.

The barrier metal 5 is provided on a region of the first main surface S1 of the semiconductor substrate 50 where the interlayer insulating film 4 is not provided, the side wall of the dummy trench 12T, the separation insulating film 18, and the interlayer insulating film 4. The barrier metal 5 is, for example, a conductor containing titanium (Ti). The barrier metal 5 is, for example, titanium nitride or TiSi obtained by alloying titanium and silicon (Si). As illustrated in FIGS. 4 and 5, the barrier metal 5 is electrically connected to the n+ type source layer 13 and the p+ type contact layer 14.

The emitter electrode 6 is provided on the barrier metal 5. The emitter electrode 6 may be, for example, formed of an aluminum alloy such as an aluminum silicon alloy (Al—Si alloy) or may be, for example, an electrode including a plurality of metal films in which a plating film is formed by electroless plating or electrolytic plating on an electrode formed of an aluminum alloy. The plating film formed by electroless plating or electrolytic plating may be, for example, a nickel (Ni) plating film or a copper (Cu) plating film.

Note that the RC-IGBT 101 may be configured not to include the barrier metal in the IGBT region 10, and the emitter electrode 6 may be directly provided on the n+ type source layer 13, the p+ type contact layer 14, and the dummy gate electrode 12a. Furthermore, the barrier metal 5 may be provided only on an n type semiconductor layer such as the n+ type source layer 13. The barrier metal 5 may be provided only on the upper surface of the n+ type source layer 13 that constitutes the first main surface S1 of the semiconductor substrate 50, in other words, may be configured not to be provided on the side wall of the dummy trench 12T. According to this configuration, it is possible to ensure an ohmic property between the n+ type source layer 13 and the emitter electrode 6 by the barrier metal 5 on the first main surface S1 since the barrier metal 5 has a good ohmic property with the n+ type source layer 13, and it is possible to ensure an ohmic property between the p type base layer 15 and the emitter electrode 6 on the side wall of the dummy trench 12T. In a case where a sputtering film formation method having strong rectilinearity is used, the barrier metal 5 can be formed while avoiding the steep side wall of the dummy trench 12T. The barrier metal 5 and the emitter electrode 6 may be collectively referred to as an emitter electrode.

The collector electrode 7 is provided on a second main surface S2 side of the p type collector layer 16. Similarly to the emitter electrode 6, the collector electrode 7 may be made of an aluminum alloy or an aluminum alloy and a plating film. The collector electrode 7 may have a configuration different from that of the emitter electrode 6. The collector electrode 7 is in ohmic contact with the p type collector layer 16 and is electrically connected to the p type collector layer 16.

Although the barrier metal 5 is illustrated in FIGS. 4 and 5, the RC-IGBT 101 may be configured not to include the barrier metal 5 in the IGBT region 10 as long as the emitter electrode 6 is an Al electrode or an Al alloy electrode. In this case, the emitter electrode 6 is in direct contact with the upper surface of the semiconductor substrate 50 exposed from the first contact hole 17 and the side wall of the dummy trench 12T. In a case where the Al electrode or the Al alloy electrode having a good ohmic property with a p type diffusion layer is directly connected to the p type base layer 15 or a p+ type side wall contact layer 19, contact resistance between the emitter electrode 6 and the p type base layer 15 is reduced, resistance of the hole discharge path is lowered, and the latch-up resistance is improved. Furthermore, since the contact resistance between the emitter electrode 6 and the p type base layer 15 is reduced, the RC-IGBT 101 may be configured not to include the p+ type contact layer 14. This can save a cost for the p+ type contact layer 14. The same applies to other preferred embodiments.

### B-2. Effects of IGBT Region

In the RC-IGBT 101 of the first preferred embodiment, the semiconductor substrate 50 includes the n− type drift layer 1 provided in the IGBT region 10 and the diode region 20, the p type base layer 15 provided on the n− type drift layer 1 in the IGBT region 10, and the n+ type source layer 13 that is provided on the p type base layer 15 in the IGBT region 10, constitutes the upper surface of the semiconductor substrate 50, and has a higher n− type impurity concentration than the n− type drift layer 1. In the semiconductor substrate 50, the plurality of gate trenches 11T and the plurality of dummy trenches 12T whose longitudinal direction is the first direction are provided in the IGBT region 10 so as to penetrate the p type base layer 15 from the upper surface of the semiconductor substrate 50 and reach the n− type drift layer 1. Furthermore, the RC-IGBT 101 further includes the plurality of gate electrodes 11a provided in the plurality of gate trenches 11T with the gate insulating film 11b interposed therebetween, the plurality of dummy gate electrodes 12a provided in the plurality of dummy trenches 12T with the dummy gate insulating film 12b interposed therebetween and having upper surfaces located below the upper surfaces of the plurality of gate electrodes 11a, the interlayer insulating film 4 provided on the upper surface of the semiconductor substrate 50 in the IGBT region 10 and having the first contact hole 17 in which at least one side wall of each dummy trench 12T is exposed above a corresponding dummy gate electrode 12a, and the emitter electrode 6 provided on the interlayer insulating film 4 and in the first contact hole 17 in the IGBT region 10 and electrically connected to the p type base layer on the side wall of each dummy trench 12T exposed to the first contact hole 17. At least one dummy trench 12T is disposed between two gate trenches 11T. According to the above configuration, the upper surfaces of the dummy gate electrodes 12a are located below the upper surfaces of the gate electrodes 11a, and the emitter electrode 6 is in contact with the n+ type source layer 13 on the side wall of each dummy trench 12T above a corresponding dummy gate electrode 12a. Therefore, this contact region can be used as a hole discharge path. As a result, a distance of the hole discharge path is shortened. This reduces the pinch resistance and improves the latch-up tolerance. Therefore, the latch-up tolerance can be maintained even if the active mesa width is reduced, and both maintenance of the latch-up tolerance and loss improvement can be realized.

### B-3. Diode Region

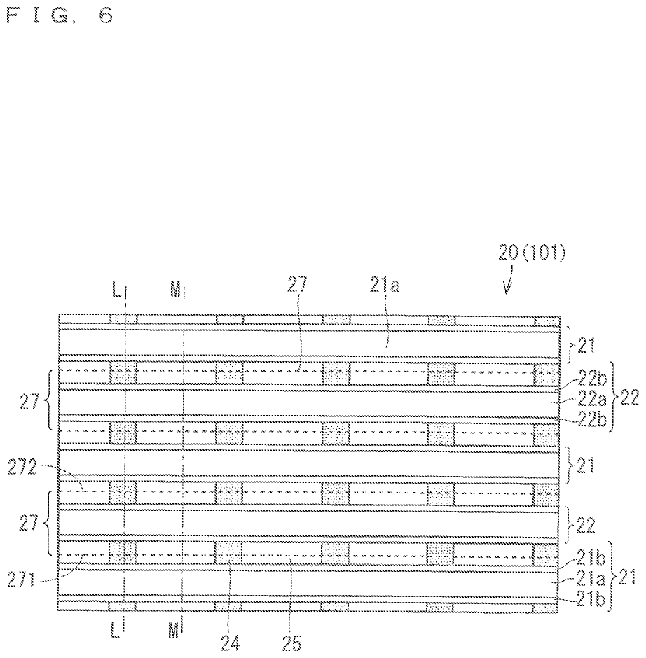

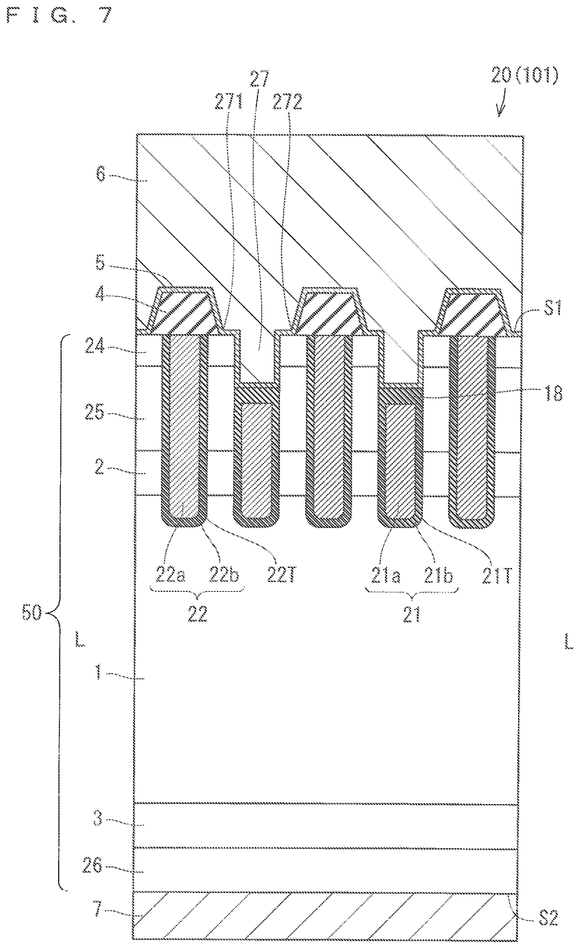

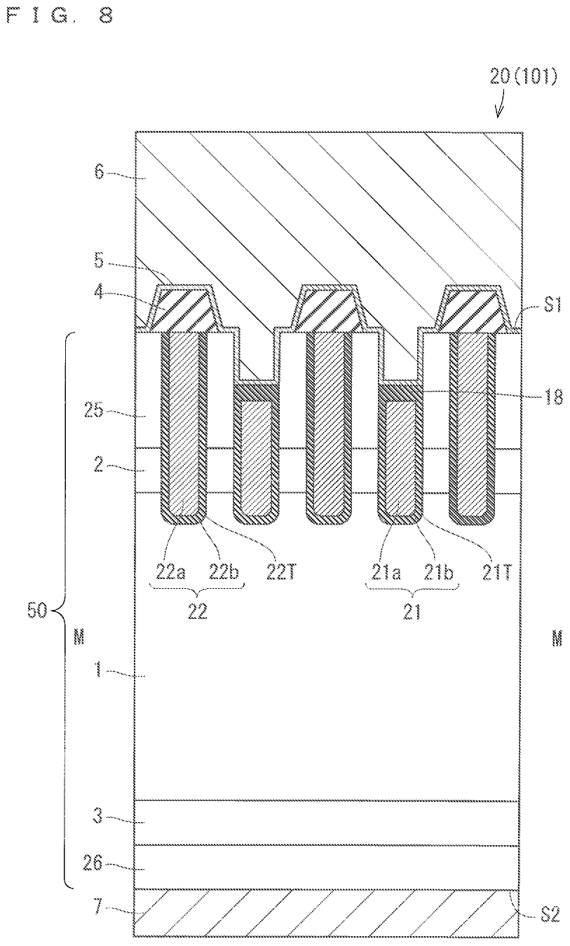

FIG. 6 is a partially enlarged plan view illustrating a configuration of the diode region 20 in the RC-IGBT 101 according to the first preferred embodiment. FIG. 6 is an enlarged view of a region surrounded by the broken line 83 in the RC-IGBT 100A illustrated in FIG. 1 or the RC-IGBT 100B illustrated in FIG. 2. FIG. 7 is a cross-sectional view of the diode region 20 taken along dashed line L-L in FIG. 6. FIG. 8 is a cross-sectional view of the diode region 20 taken along dashed line M-M in FIG. 6.

As illustrated in FIG. 6, the RC-IGBT 101 includes a first diode trench gate 21 and a second diode trench gate 22 extending from one end side to the other end side of the diode region 20 in the diode region 20. The first diode trench gate 21 and the second diode trench gate 22 both extend in a longitudinal direction of the diode region 20. In the case of the island-type RC-IGBT 100B, there is no distinction between a longitudinal direction and a lateral direction of the diode region 20, but either the left-right direction or the up-down direction of the paper on which FIG. 2 is drawn may be set as the longitudinal direction of the first diode trench gate 21 and the second diode trench gate 22.

As illustrated in FIGS. 6 to 8, the first diode trench gate 21 includes a first diode trench insulating film 21b and a first diode trench electrode 21a. A diode trench 21T is provided in the semiconductor substrate 50. The first diode trench insulating film 21b is provided on a part of a side wall and a bottom surface of the diode trench 21T. The first diode trench electrode 21a is provided in the diode trench 21T with the first diode trench insulating film 21b interposed therebetween.

The second diode trench gate 22 includes a second diode trench insulating film 22b and a second diode trench electrode 22a. A diode trench 22T is provided in the semiconductor substrate 50. The second diode trench insulating film 22b is provided on a side wall and a bottom surface of the diode trench 22T. The second diode trench electrode 22a is provided in the diode trench 22T with the second diode trench insulating film 22b interposed therebetween.

As illustrated in FIG. 6, the RC-IGBT 101 includes a p+ type contact layer 24 and a p type anode layer 25 in the diode region 20. FIG. 6 illustrates the p+ type contact layer 24 and the p type anode layer 25 on the first main surface S1 of the semiconductor substrate 50. The p+ type contact layer 24 and the p type anode layer 25 are provided in contact with the first diode trench insulating film 21b between the first diode trench gate 21 and the second diode trench gate 22 that are adjacent to each other. However, the p+ type contact layer 24 and the p type anode layer 25 need not necessarily be in contact with the first diode trench insulating film 21b. Furthermore, the p+ type contact layer 24 and the p type anode layer 25 are alternately arranged along the longitudinal direction of the first diode trench gate 21 and the second diode trench gate 22 on the first main surface S1 of the semiconductor substrate 50. The p+ type contact layer 24 is a semiconductor layer containing, for example, boron or aluminum as a p type impurity. A concentration of the p type impurity in the p+ type contact layer 24 is 1.0×10¹⁵/cm³ or more and 1.0×10²⁰/cm³ or less. The p type anode layer 25 is a semiconductor layer containing, for example, boron or aluminum as a p type impurity. A concentration of the p type impurity in the p type anode layer 25 is 1.0×10¹²/cm³ or more and 1.0×10¹⁹/cm³ or less.

As illustrated in FIGS. 7 and 8, the RC-IGBT 110 includes the n− type drift layer 1, the n type carrier accumulation layer 2, the p type anode layer 25, the n type buffer layer 3, and an n+ type cathode layer 26 in the diode region 20. Furthermore, as illustrated in FIG. 7, the RC-IGBT 101 includes the p+ type contact layer 24 in the diode region 20. The p+ type contact layer 24 provided on the first main surface S1 side of the semiconductor substrate 50 in contact with the first diode trench gate 21 and the second diode trench gate 22 in FIG. 7 is not seen in FIG. 8. That is, as illustrated in FIG. 6, the p+ type contact layer 24 is intermittently provided in a surface layer of the p type anode layer 25 along the longitudinal direction of the diode trenches 21T and 22T. Hole injection efficiency from an anode side varies depending on arrangement of the p+ type contact layer 24, and it is therefore possible to control trade-off between a conduction loss and a recovery loss of the diode.

The n− type drift layer 1 of the diode region 20 is continuous and integral with the n− type drift layer 1 in the IGBT region 10, and is formed of the same semiconductor substrate 50. The semiconductor substrate 50 corresponds to a range from the p+ type contact layer 24 to the n+ type cathode layer 26 in FIG. 7, and corresponds to a range from the p type anode layer 25 to the n+ type cathode layer 26 in FIG. 8. An upper end of the p+ type contact layer 24 on the paper on which FIG. 7 is drawn or an upper end of the p type anode layer 25 on the paper on which FIG. 8 is drawn is referred to as the first main surface S1 of the semiconductor substrate 50, and a lower end of the n+ type cathode layer 26 on the paper on which FIGS. 7 and 8 are drawn is referred to as the second main surface S2 of the semiconductor substrate 50. The first main surface S1 of the diode region 20 and the first main surface S1 of the IGBT region 10 are the same surface, and the second main surface S2 of the diode region 20 and the second main surface S2 of the IGBT region 10 are the same surface.

In the diode region 20, the n type carrier accumulation layer 2 is provided on a first main surface S1 side of the n− type drift layer 1, and the n type buffer layer 3 is provided on a second main surface S2 side of the n− type drift layer 1. The n type carrier accumulation layer 2 and the n type buffer layer 3 in the diode region 20 have identical configurations to the n type carrier accumulation layer 2 and the n type buffer layer 3 in the IGBT region 10. The n type carrier accumulation layer 2 need not necessarily be provided in the IGBT region 10 and the diode region 20. It is also possible to employ a configuration in which the n type carrier accumulation layer 2 is provided in the IGBT region 10 but is not provided in the diode region 20. The n− type drift layer 1, the n type carrier accumulation layer 2, and the n type buffer layer 3 in the diode region 20 may be collectively referred to as a drift layer, as in the IGBT region 10.

In the diode region 20, the p type anode layer 25 is provided on a first main surface S1 side of the n type carrier accumulation layer 2. The p type anode layer 25 is provided between the n− type drift layer 1 and the first main surface S1. The concentration of the p type impurity in the p type anode layer 25 may be the same as the concentration of the p type impurity in the p type base layer 15 in the IGBT region 10. In this case, the p type anode layer 25 and the p type base layer 15 can be formed simultaneously. The concentration of the p type impurity in the p type anode layer 25 may be lower than the concentration of the p type impurity in the p type base layer 15 in the IGBT region 10. In this case, an amount of holes injected into the diode region 20 during diode operation decreases, and therefore recovery loss during diode operation is reduced.

In the diode region 20, the p+ type contact layer 24 is provided on a first main surface S1 side of a part of the p type anode layer 25. The concentration of the p impurity in the p+ type contact layer 24 may be the same as or different from the concentration of the p impurity in the p+ type contact layer 14 in the IGBT region 10. An upper surface of the p+ type contact layer 24 constitutes the first main surface S1 of the semiconductor substrate 50, and an upper surface of the p type anode layer 25 constitutes the first main surface S1 of the semiconductor substrate 50 in a region where the p+ type contact layer 24 is not provided. The p+ type contact layer 24 is a region having a higher p type impurity concentration than the p type anode layer 25. In a case where the p+ type contact layer 24 and the p type anode layer 25 need not be distinguished from each other, the p+ type contact layer 24 and the p type anode layer 25 may be collectively referred to as a p type anode layer.

In the diode region 20, the n+ type cathode layer 26 is provided on a second main surface S2 side of the n type buffer layer 3. That is, the n+ type cathode layer 26 is provided between the n− type drift layer 1 and the second main surface S2. The n+ type cathode layer 26 is a semiconductor layer containing, for example, arsenic or phosphorus as an n type impurity. A concentration of the n type impurity in the n+ type cathode layer 26 is 1.0×10¹⁶/cm³ or more and 1.0×10²¹/cm³ or less. The n+ type cathode layer 26 is provided in a part or all of the diode region 20. A lower surface of the n+ type cathode layer 26 constitutes the second main surface S2 of the semiconductor substrate 50. Although not illustrated, a p type impurity may be implanted into a part of the region where the n+ type cathode layer 26 is formed to form a p type cathode layer. A diode having a configuration in which a n+ type cathode layer and a p+ type cathode layer are alternately arranged along the second main surface S2 of the semiconductor substrate 50 is also referred to as a Relaxed Field of Cathode (RFC) diode. In the RFC diode, the p+ type cathode layer is arranged in a stripe shape or a dot shape in the diode region 20. The width of the stripe or dot is 1 μm or more and about the thickness of the semiconductor substrate 50 or less, and an area occupied by the p+ cathode layer is about 0% or more and 80% or less.

As illustrated in FIGS. 7 and 8, in the diode region 20 of the RC-IGBT 101, a plurality of diode trenches 21T and 22T that penetrate the p type anode layer 25 from the first main surface S1 of the semiconductor substrate 50 and reach the n− type drift layer 1 are provided. In each diode trench 21T, the first diode trench electrode 21a is provided with the first diode trench insulating film 21b interposed therebetween to form the first diode trench gate 21. In the diode trench 22T, the second diode trench electrode 22a is provided with the second diode trench insulating film 22b interposed therebetween to form the second diode trench gate 22. Hereinafter, the first diode trench gate 21 and the second diode trench gate 22 are also collectively referred to as a diode trench gate. An upper surface of the first diode trench electrode 21a is at a position lower than the first main surface S1 of the semiconductor substrate 50, and an upper surface of the second diode trench electrode 22a is at the same height as the first main surface S1 of the semiconductor substrate 50. The first diode trench electrode 21a and the second diode trench electrode 22a face the n− type drift layer 1 with the first diode trench insulating film 21b interposed therebetween. Since the upper surface of the first diode trench electrode 21a is lower than the first main surface S1 of the semiconductor substrate 50, the emitter electrode 6 can be brought into contact with the side wall of the diode trench 21T above the first diode trench electrode 21a. That is, the emitter electrode 6 is electrically connected to the p type anode layer 25 and the p+ type contact layer 24 on the side wall of the diode trench 21T above the first diode trench electrode 21a.

The separation insulating film 18 may be provided between the first diode trench electrode 21a and the emitter electrode 6, and thereby the first diode trench electrode 21a and the emitter electrode 6 may be electrically separated. Alternatively, there may be no separation insulating film 18 between the first diode trench electrode 21a and the emitter electrode 6, and the first diode trench electrode 21a and the emitter electrode 6 may be directly connected in the diode trench 21T. In a case where the separation insulating film 18 is provided between the first diode trench electrode 21a and the emitter electrode 6, a part of the first diode trench electrode 21a may be connected to the gate electrode 11a by a wiring (not illustrated).

As illustrated in FIGS. 7 and 8, the RC-IGBT 101 includes the interlayer insulating film 4, the barrier metal 5, the emitter electrode 6, and the collector electrode 7 in the diode region 20. The interlayer insulating film 4 is provided on the first main surface S1 of the semiconductor substrate 50 in the diode region 20 and covers the second diode trench electrode 22a. As illustrated in FIG. 6, a second contact hole 27 of the interlayer insulating film 4 extends in the longitudinal direction of the first diode trench gate 21 and the second diode trench gate 22. Furthermore, as illustrated in FIGS. 7 and 8, one end 271 and the other end 272 of the second contact hole 27 are on the p+ type contact layer 24 or the p type anode layer 25 between the adjacent first diode trench gate 21 and second diode trench gate 22.

In the diode region 20, the barrier metal 5 is provided on a region of the first main surface S1 of the semiconductor substrate 50 where the interlayer insulating film 4 is not provided, the side wall of the diode trench 21T, the separation insulating film 18, and the interlayer insulating film 4. A material of the barrier metal 5 in the diode region may be similar to the material of the barrier metal 5 in the IGBT region 10. As illustrated in FIGS. 7 and 8, the barrier metal 5 is electrically connected to the p+ type contact layer 24 and the p type anode layer 25.

The emitter electrode 6 is provided on the barrier metal 5 in the diode region 20. A material of the emitter electrode 6 in the diode region 20 is similar to the material of the emitter electrode 6 in the IGBT region 10. The emitter electrode 6 in the diode region 20 is continuous with the emitter electrode 6 in the IGBT region 10.

The collector electrode 7 is provided on the second main surface S2 side of the n+ type cathode layer 26 in the diode region 20. Similarly to the emitter electrode 6, the collector electrode 7 in the diode region 20 is continuous with the collector electrode 7 in the IGBT region 10. The collector electrode 7 is in ohmic contact with the n+ type cathode layer 26 and is electrically connected to the n+ type cathode layer 26.

In FIGS. 6 to 8, the first diode trench gate 21 above which the second contact hole 27 is disposed and the second diode trench gate 22 above which the second contact hole 27 is not disposed are alternately arranged. However, the arrangement of the first diode trench gate 21 and the second diode trench gate 22 is not limited to this. The second diode trench gate 22 need not necessarily be provided. That is, all the diode trench gates disposed in the diode region 20 may be the first diode trench gate 21.

Although the barrier metal 5 is illustrated in FIGS. 7 and 8, the RC-IGBT 101 may be configured not to include the barrier metal 5 in the diode region 20 as long as the emitter electrode 6 is an Al electrode or an Al alloy electrode. In this case, the emitter electrode 6 is in direct contact with the upper surface of the semiconductor substrate 50 exposed from the second contact hole 27 and the side wall of the diode trench 21T. In a case where an Al electrode or an Al alloy electrode having a good ohmic property with the p type diffusion layer is directly connected to the p type anode layer 25, contact resistance between the p type anode layer 25 and the emitter electrode 6 in the current path is reduced, an on-voltage of the diode is reduced, and conduction loss is improved. Furthermore, in this case, since the contact resistance between the emitter electrode 6 and the p type anode layer 25 is reduced, the RC-IGBT 101 may be configured not to include the p+ type contact layer 24. This can save a cost for the p+ type contact layer 24. The same applies to other preferred embodiments.

The upper surface of the first diode trench electrode 21a in the diode region 20 may be at the same height as the upper surface of the dummy gate electrode 12a in the IGBT region 10. This makes it possible to simultaneously form the dummy gate electrode 12a in the IGBT region 10 and the first diode trench electrode 21a in the diode region 20, thereby suppressing an increase in the number of manufacturing processes.

### B-4. Effects of Diode Region

In the RC-IGBT 101 of the first preferred embodiment, the semiconductor substrate 50 includes the p type anode layer 25 that is provided on the n− type drift layer 1 in the diode region 20 and constitutes the upper surface of the semiconductor substrate 50, the plurality of diode trenches 21T and 22T whose longitudinal directions are the same and that penetrate the p type anode layer 25 from the upper surface of the semiconductor substrate 50 and reach the n− type drift layer 1, and a plurality of diode trench electrodes provided in the diode trenches 21T and 22T with a diode trench insulating film interposed therebetween. At least one of the plurality of diode trench electrodes is the first diode trench electrode 21a having an upper surface lower than the upper surface of the p type anode layer 25. The interlayer insulating film 4 is provided on the upper surface of the semiconductor substrate 50 in the diode region 20, and has the second contact hole 27 in which the side wall of each diode trench 21T is exposed above the first diode trench electrode 21a. The emitter electrode 6 is provided on the interlayer insulating film 4 and in the second contact hole 27 in the diode region 20, and is electrically connected to the p type anode layer 25 on the side wall of each diode trench 21T exposed to the second contact hole 27. With the above configuration, the p type anode layer 25 and the emitter electrode 6 are in contact with each other on the side wall of the diode trench 21T above the first diode trench electrode 21a, and this contact portion function as an electron discharge path. As a result, an internal charge during diode energization is reduced, and a recovery current and recovery loss are reduced.

### C. Second Preferred Embodiment

### C-1. Configuration

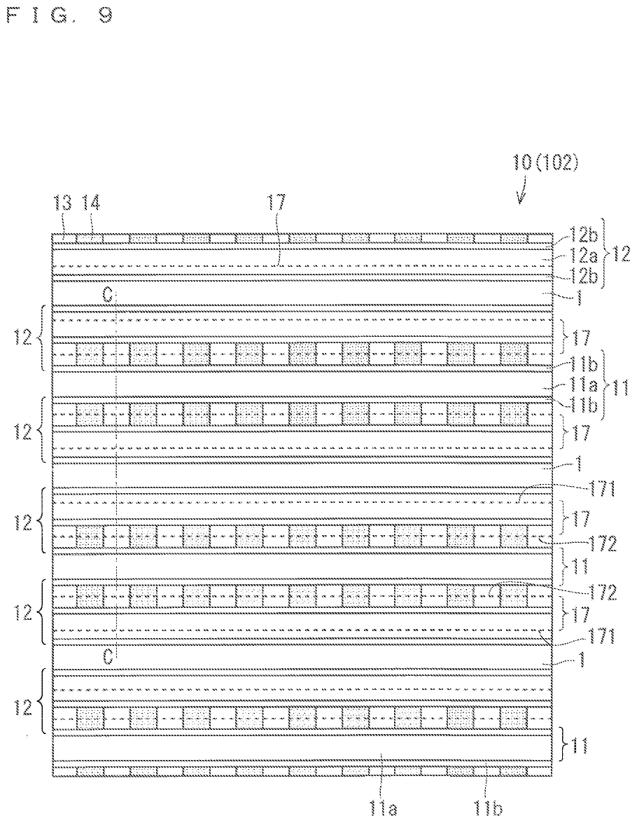

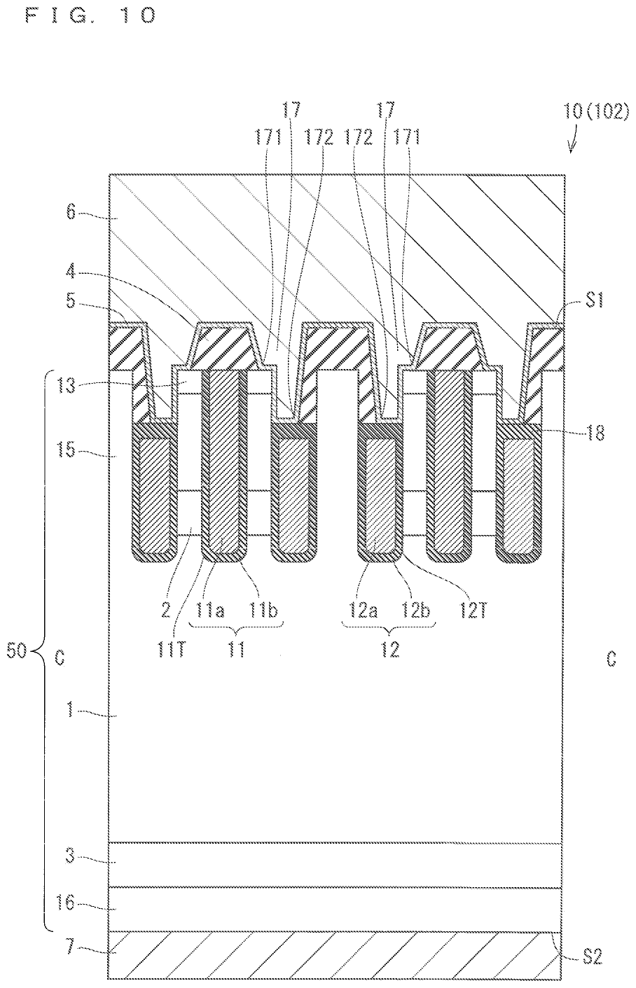

FIG. 9 is a partially enlarged plan view illustrating a configuration of an IGBT region 10 in an RC-IGBT 102 according to a second preferred embodiment. Either the RC-IGBT 101A illustrated in FIG. 1 or the RC-IGBT 100B illustrated in FIG. 2 is applied as the RC-IGBT 102 according to the second preferred embodiment. FIG. 9 is an enlarged view of a region surrounded by the broken line 82 in the RC-IGBT 100A illustrated in FIG. 1 or the RC-IGBT 100B illustrated in FIG. 2. FIG. 10 is a cross-sectional view of the IGBT region 10 taken along dashed line C-C in FIG. 9. A cross section corresponding to FIG. 5 of the first preferred embodiment is omitted because a difference lies only in that the n+ type source layer 13 in FIG. 10 is replaced with a p+ type contact layer 14.

FIG. 9 illustrates an example in which two dummy trench gates 12 are disposed between two active trench gates 11.

As illustrated in FIG. 10, an interlayer insulating film 4 is provided not only on a gate electrode 11a but also on a portion of the dummy trench gate 12 on a side opposite to the active trench gate 11. That is, the interlayer insulating film 4 covers a region between the dummy trench 12T adjacent to the gate trench 11T on one side and adjacent to another dummy trench 12T on the other side and the other dummy trench 12T. One end 171 of a first contact hole 17 is located on a portion between the active trench gate 11 and the dummy trench gate 12, and the other end 172 is located on the dummy trench gate 12. With the above configuration, a current path of the dummy trench gate 12 on a side opposite to the active trench gate 11 is blocked. This enhances an accumulation effect, increases a carrier density on an emitter side during energization, further reduces an on-voltage, and improves the loss.

As illustrated in FIG. 10, a p type base layer 15 is not provided between the two dummy trench gates 12 on a side opposite to the active trench gate 11. That is, the p type base layer 15 is not provided between the dummy trench 12T adjacent to the gate trench 11T on one side and adjacent to another dummy trench 12T on the other side and the other dummy trench 12T, and an upper surface of an n− type drift layer 1 constitutes a first main surface S1 of a semiconductor substrate 50. This can keep the floating p type base layer from deteriorating gate controllability. If the p type base layer 15 is provided on a side of the dummy trench gate 12 opposite to the active trench gate 11, the floating p type base layer 15 is charged with holes, and the holes flow into the gate electrode 11a at turn-on of switching. This accelerates switching operation, thereby deteriorating controllability of a switching speed. In order to suppress this deterioration in controllability, the p type base layer 15 is not provided on the side of the dummy trench gate 12 opposite to the active trench gate 11.

Although FIGS. 9 and 10 illustrate an example in which two dummy trench gates 12 are disposed between two active trench gates 11, three or more dummy trench gates 12 may be disposed between two active trench gates 11. In a case where three or more dummy trench gates 12 are disposed between two active trench gates 11, the dummy trench gate 12 that is not adjacent to the active trench gate 11 may be gate-connected or emitter-connected. In a configuration in which four or more dummy trench gates 12 are disposed between two active trench gates 11, in a case where one or more dummy trench gates 12 are present between each of two adjacent dummy trench gates 12 and the nearest active trench gate 11, the p type base layer 15 may be disposed between the two adjacent dummy trench gates 12 as long as the two adjacent dummy trench gates 12 are emitter-connected.

### C-2. Effects

In the RC-IGBT 102 of the second preferred embodiment, two or more dummy trenches 12T are disposed between two gate trenches 11T. Furthermore, the interlayer insulating film 4 covers a region between the dummy trench 12T adjacent to the gate trench 11T on one side and adjacent to another dummy trench 12T on the other side and the other dummy trench 12T. With the above configuration, the current path of the dummy trench gate 12 on the side opposite to the active trench gate 11 is blocked. This enhances an accumulation effect, increases a carrier density on an emitter side during energization, further reduces an on-voltage, and improves loss.

Furthermore, in the RC-IGBT 102, the p type base layer 15 is not provided between the dummy trench 12T adjacent to the gate trench 11T on one side and adjacent to another dummy trench 12T on the other side and the other dummy trench 12T. With the above configuration, a floating p type base layer is not provided on a side of the dummy trench gate 12 opposite to the active trench gate 11. If the p type base layer is charged with holes, the holes flow into the gate electrode 11a at turn-on of switching. This accelerates switching operation, thereby deteriorating controllability of a switching speed. However, in the RC-IGBT 102, the above problem can be avoided.

### D. Third Preferred Embodiment

### D-1. Configuration

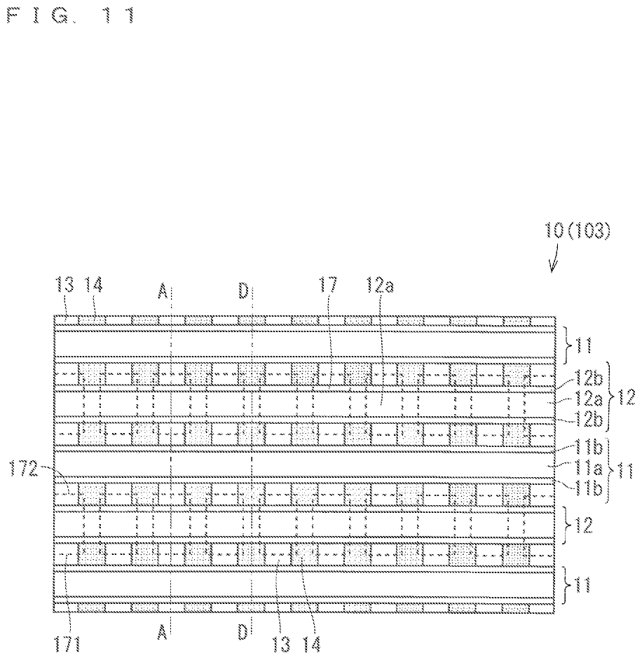

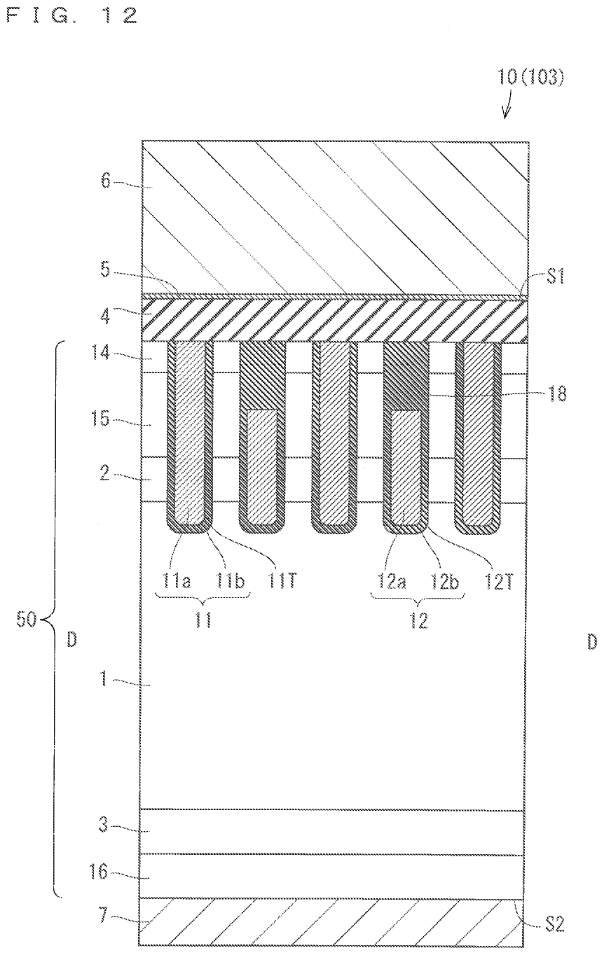

FIG. 11 is a partially enlarged plan view illustrating a configuration of an IGBT region 10 in an RC-IGBT 103 according to a third preferred embodiment. Either the RC-IGBT 101A illustrated in FIG. 1 or the RC-IGBT 100B illustrated in FIG. 2 is applied as the RC-IGBT 103 according to the third preferred embodiment. FIG. 11 is an enlarged view of a region surrounded by the broken line 82 in the RC-IGBT 100A illustrated in FIG. 1 or the RC-IGBT 100B illustrated in FIG. 2. FIG. 12 is a cross-sectional view of the IGBT region 10 taken along dashed line D-D in FIG. 11. A cross-sectional view of the IGBT region 10 taken along dashed line A-A in FIG. 11 is identical to that illustrated in FIG. 4.

As illustrated in FIGS. 11 and 12, an n+ type source layer 13 is intermittently disposed in a longitudinal direction of an active trench gate 11 and a dummy trench gate 12. A first contact hole 17 is not disposed in a portion above the dummy trench gate 12 that is adjacent to a portion where the n+ type source layer 13 is not disposed.

### D-2. Effects

In the RC-IGBT 103 of the third preferred embodiment, an interlayer insulating film 4 has the first contact hole 17 above a region of the dummy trench 12T that is adjacent to the n+ type source layer 13, and does not have the first contact hole 17 above a region of the dummy trench 12T that is not adjacent to the n+ type source layer 13, in other words, above a region of the dummy trench 12T that is adjacent to a p+ type contact layer 14. This can reduce the number of hole discharge paths as a whole while maintaining a hole discharge path from the n+ type source layer 13 and thereby increase a carrier accumulation effect. As a result, a carrier density on an emitter side during energization is increased, an on-voltage is reduced, and loss is improved.

### E. Fourth Preferred Embodiment

### E-1. Configuration

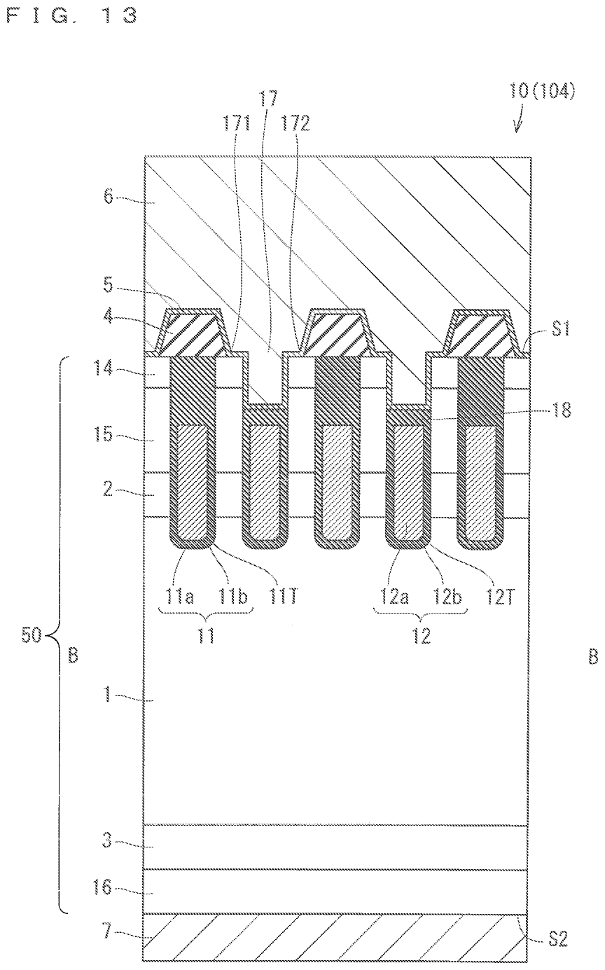

A partially enlarged plan view illustrating a configuration of an IGBT region 10 in an RC-IGBT 104 of a fourth preferred embodiment is similar to the partially enlarged plan view illustrating the configuration of the IGBT region 10 in the RC-IGBT 101 of the first preferred embodiment illustrated in FIG. 3. FIG. 13 is a cross-sectional view of the IGBT region 10 in the RC-IGBT 104 taken along dashed line B-B in FIG. 3. A cross-sectional view of the IGBT region 10 in the RC-IGBT 104 taken along dashed line A-A in FIG. 3 is identical to that illustrated in FIG. 4.

As illustrated in FIG. 13, an upper end of a region of a gate electrode 11a that faces a p+ type contact layer 14 with a gate insulating film 11b interposed therebetween is at the same height as an upper end of a dummy gate electrode 12a.

### E-2. Effects

In the RC-IGBT 104 of the fourth preferred embodiment, an upper surface of a portion of the gate electrode 11a that is not adjacent to an n+ type source layer 13 is at the same height as the upper surface of the dummy gate electrode 12a. A portion of the gate electrode 11a that is not adjacent to the n+ type source layer 13 does not contribute to channel formation. Therefore, gate capacitance can be reduced by lowering the upper surface of the portion to a level similar to the dummy gate electrode 12a.

### F. Fifth Preferred Embodiment

### F-1. Configuration

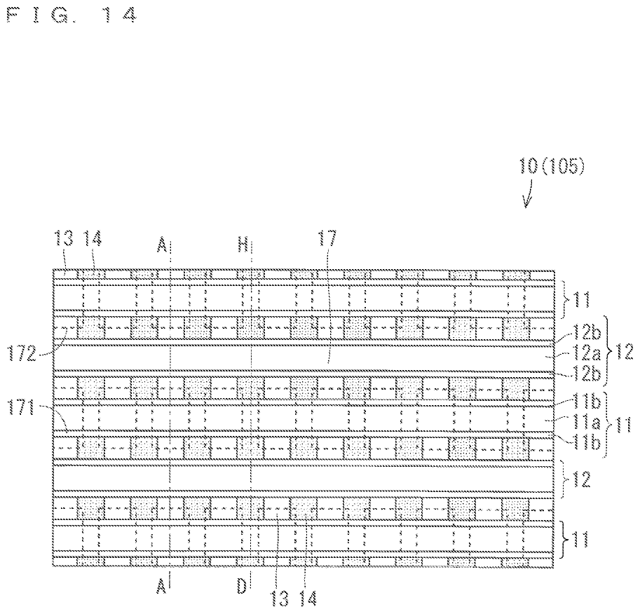

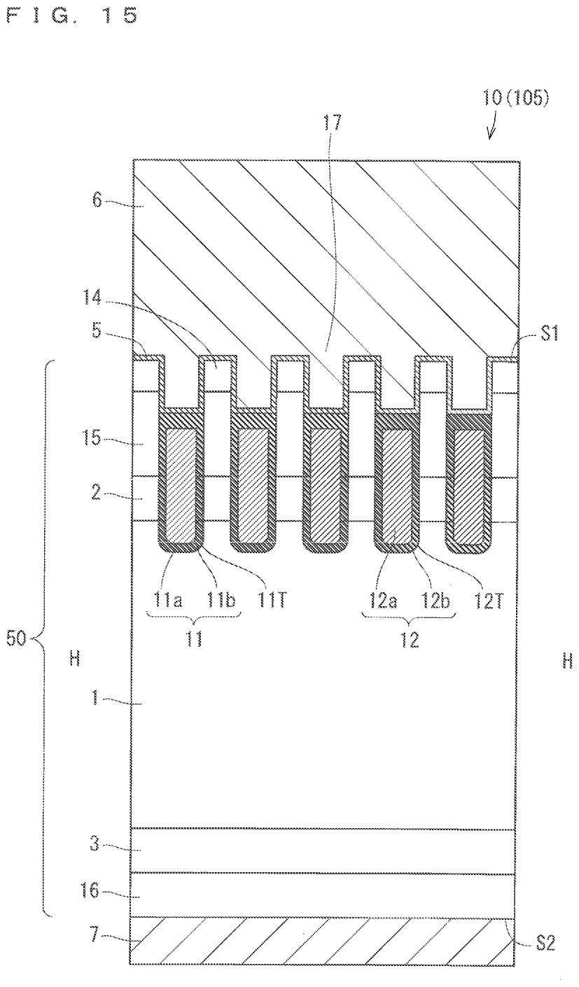

FIG. 14 is a partially enlarged plan view illustrating a configuration of an IGBT region 10 in an RC-IGBT 105 according to a fifth preferred embodiment. Either the RC-IGBT 101A illustrated in FIG. 1 or the RC-IGBT 100B illustrated in FIG. 2 is applied as the RC-IGBT 105 according to the fifth preferred embodiment. FIG. 14 is an enlarged view of a region surrounded by the broken line 82 in the RC-IGBT 100A illustrated in FIG. 1 or the RC-IGBT 100B illustrated in FIG. 2. FIG. 15 is a cross-sectional view of the IGBT region 10 taken along dashed line H-H in FIG. 14. A cross-sectional view of the IGBT region 10 taken along dashed line A-A in FIG. 15 is identical to that illustrated in FIG. 4.

As illustrated in FIGS. 14 and 15, a first contact hole 17 of an interlayer insulating film 4 is disposed above a dummy trench gate 12 and above a portion of an active trench gate 11 where an n+ type source layer 13 is not disposed, that is, above a portion of the active trench gate 11 that is adjacent to a p+ type contact layer 14.

### F-2. Effects

In the RC-IGBT 105 of the fifth preferred embodiment, the interlayer insulating film 4 does not have the first contact hole 17 above a region of the gate trench 1 IT that is adjacent to the n+ type source layer 13, and has the first contact hole 17 above a region of the gate trench 11T that is not adjacent to the n+ type source layer 13, that is, a region of the gate trench 11T that is adjacent to the p+ type contact layer 14. With this configuration, holes are discharged from the vicinity of a channel region, and latch-up tolerance is improved.

### G. Sixth Preferred Embodiment

### G-1. Configuration

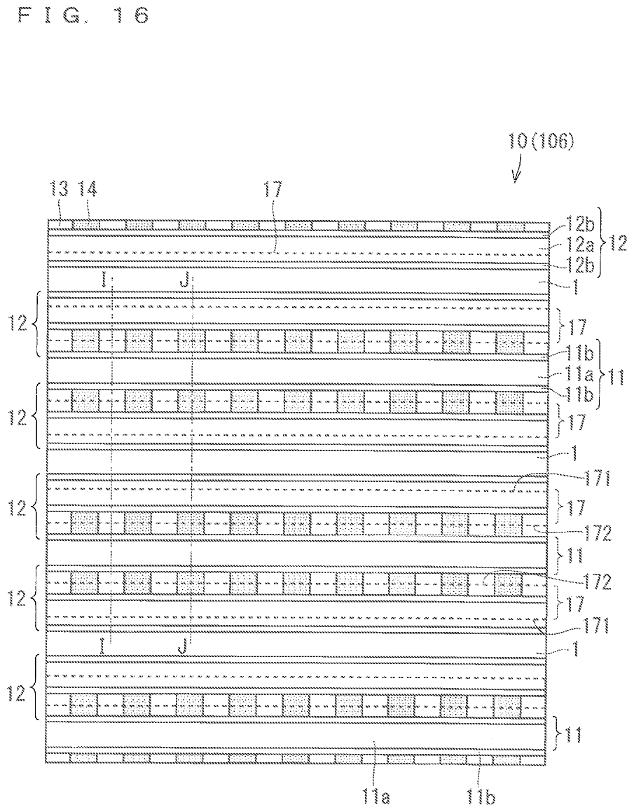

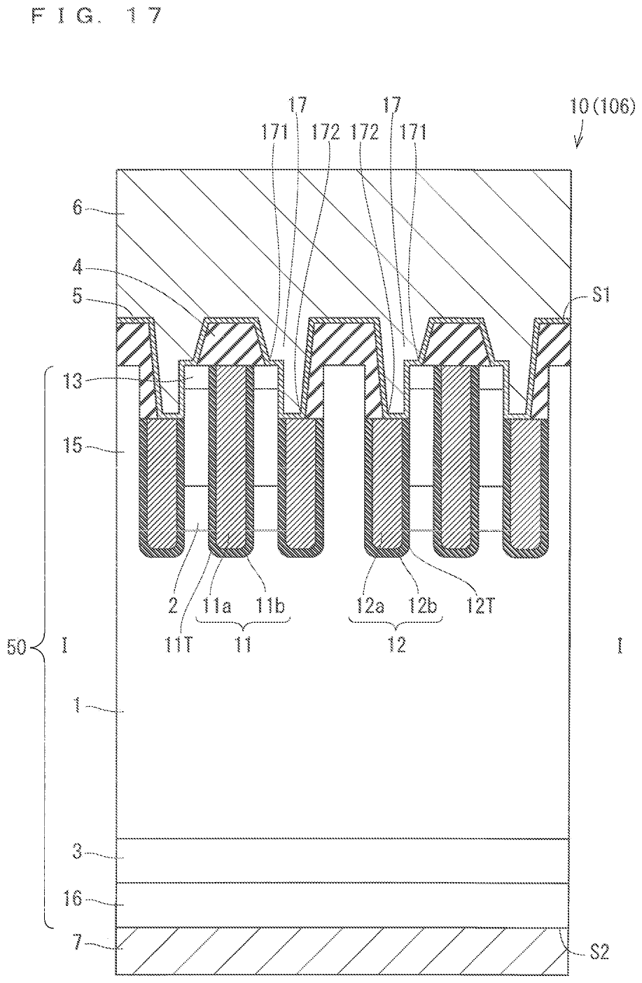

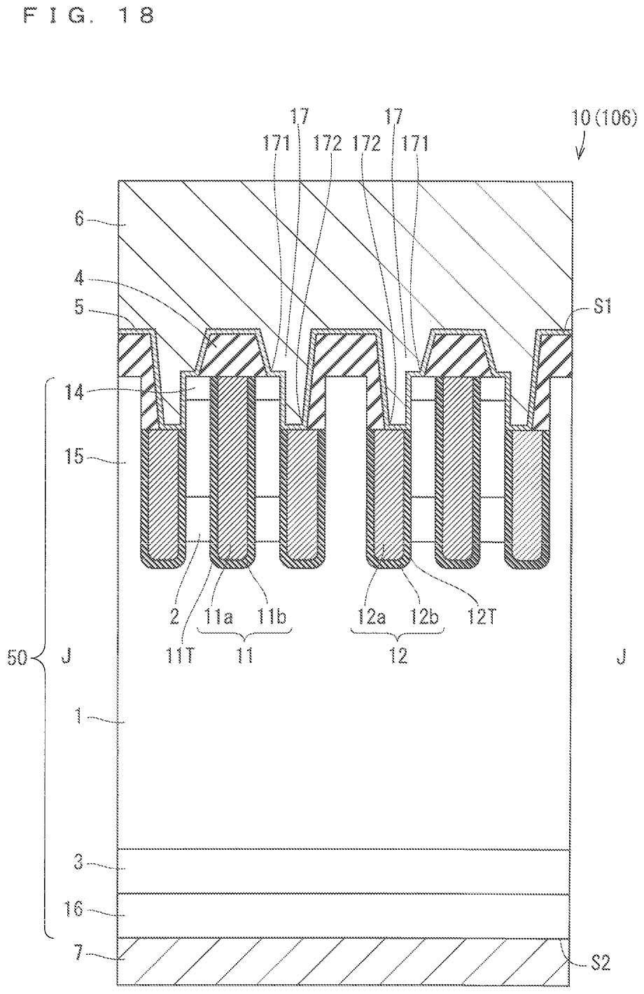

FIG. 16 is a partially enlarged plan view illustrating a configuration of an IGBT region 10 in an RC-IGBT 106 according to a sixth preferred embodiment. Either the RC-IGBT 101A illustrated in FIG. 1 or the RC-IGBT 100B illustrated in FIG. 2 is applied as the RC-IGBT 106 according to the sixth preferred embodiment. FIG. 16 is an enlarged view of a region surrounded by the broken line 82 in the RC-IGBT 100A illustrated in FIG. 1 or the RC-IGBT 100B illustrated in FIG. 2. FIG. 17 is a cross-sectional view of the IGBT region 10 taken along dashed line I-I in FIG. 16. FIG. 18 is a cross-sectional view of the IGBT region 10 taken along dashed line J-J in FIG. 16.

FIGS. 16 to 18 illustrate an example in which two dummy trench gates 12 are disposed between two active trench gates 11.

As illustrated in FIGS. 17 and 18, in the RC-IGBT 106, there is no separation insulating film 18 between a dummy gate electrode 12a and an emitter electrode 6, and the dummy gate electrode 12a is electrically connected to the emitter electrode 6 in a first contact hole 17. The dummy gate electrode 12a is not connected to a gate electrode 11a. The dummy gate electrode 12a connected to the emitter electrode 6 has an effect of reducing feedback capacitance, and has an effect of reducing switching loss by high-speed operation due to the capacitance reduction in the case of high-speed use in which dv/dt is driven at high speed. Furthermore, since the emitter electrode 6 and the dummy gate electrode 12a are directly connected in the dummy trench 12T, a potential of the dummy gate electrode 12a can be stabilized.

As illustrated in FIGS. 17 and 18, an interlayer insulating film 4 is provided not only on the gate electrode 11a but also on a portion of the dummy trench gate 12 on a side opposite to the active trench gate 11, that is, on a region sandwiched by the two dummy trench gates 12 and on a portion of the dummy trench gate 12 adjacent to the region. That is, one end 171 of the first contact hole 17 of the interlayer insulating film 4 is located on a portion between the active trench gate 11 and the dummy trench gate 12, and the other end 172 is located on the dummy trench gate 12. With the above configuration, a current path of the dummy trench gate 12 on a side opposite to the active trench gate 11 is blocked. This enhances an accumulation effect, increases a carrier density on an emitter side during energization, further reduces an on-voltage, and improves the loss.

In FIGS. 17 and 18, a p type base layer 15 is provided on a side of the dummy trench gate 12 opposite to the active trench gate 11, that is, in a region sandwiched between the two dummy trench gates 12. However, the p type base layer 15 need not necessarily be provided in this region.

Although FIGS. 16 to 18 illustrate an example in which two dummy trench gates 12 are disposed between two active trench gates 11, three or more dummy trench gates 12 may be disposed between two active trench gates 11. In a case where three or more dummy trench gates 12 are disposed between two active trench gates 11, the dummy trench gate 12 that is not adjacent to the active trench gate 11 may be gate-connected or emitter-connected. In this case, the p type base layer 15 may be disposed or need not be disposed between two adjacent dummy trench gates 12.

As illustrated in FIGS. 17 and 18, an upper surface of the dummy gate electrode 12a is below an upper surface of the gate electrode 11a. With this configuration, a region where the emitter electrode 6 is brought into contact with a side wall of the dummy trench 12T can be provided above the dummy trench gate 12. Furthermore, the upper surface of the dummy gate electrode 12a is below a lower surface of the n+ type source layer 13. With this configuration, a hole discharge path is provided at a position deeper than the lower surface of the n+ type source layer 13, and therefore the latch-up tolerance is further improved.

The n+ type source layer 13 may be configured not to be in contact with the side wall of the dummy trench 12T. However, as illustrated in FIG. 4, the n+ type source layer 13 can be connected to the emitter electrode 6 in a wide area by being in contact with the side wall of the dummy trench 12T, and thereby contact resistance is reduced.

### G-2. Effects

In the RC-IGBT 106 of the sixth preferred embodiment, each dummy gate electrode 12a is not connected to the gate electrode 11a, but is electrically connected to the emitter electrode 6 in the first contact hole 17. The dummy gate electrode 12a connected to the emitter electrode 6 has an effect of reducing feedback capacitance, and has an effect of reducing switching loss by high-speed operation due to the capacitance reduction in the case of high-speed use in which dv/dt is driven at high speed. Furthermore, since the emitter electrode 6 and the dummy gate electrode 12a are directly connected in the dummy trench 12T, a potential of the dummy gate electrode 12a can be stabilized.

### H. Seventh Preferred Embodiment

### H-1. Configuration

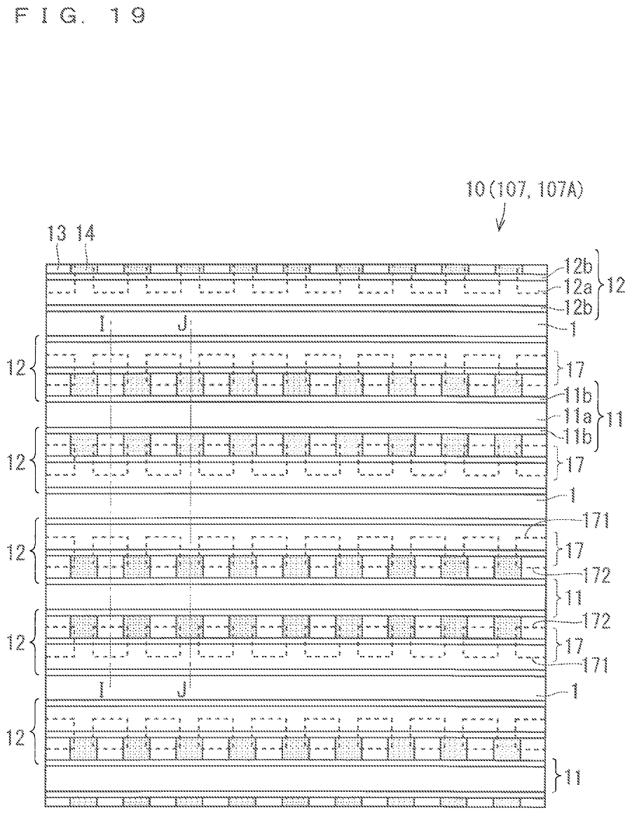

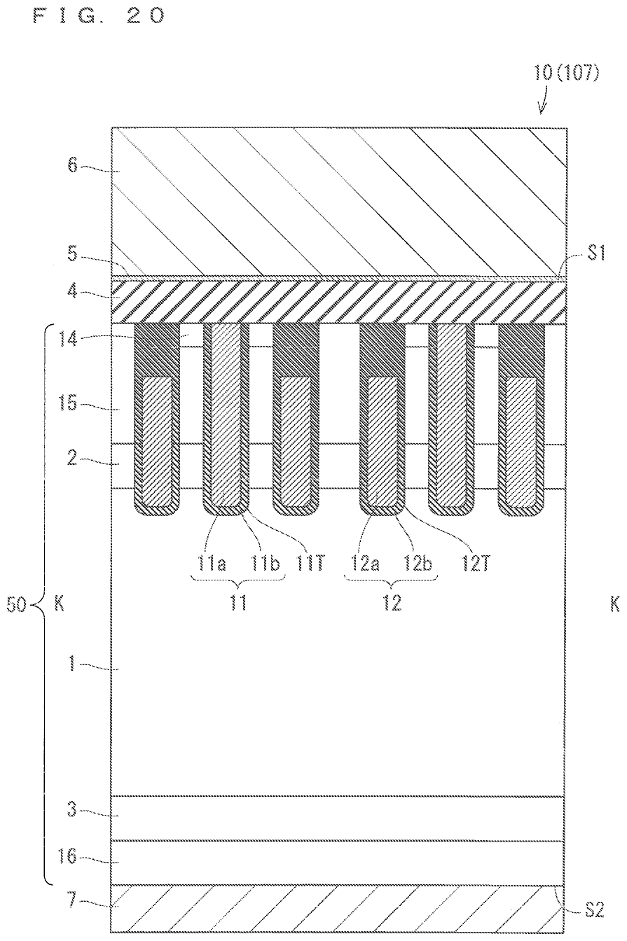

FIG. 19 is a partially enlarged plan view illustrating a configuration of an IGBT region 10 in an RC-IGBT 107 according to a seventh preferred embodiment. Either the RC-IGBT 101A illustrated in FIG. 1 or the RC-IGBT 100B illustrated in FIG. 2 is applied as the RC-IGBT 107 according to the seventh preferred embodiment. FIG. 19 is an enlarged view of a region surrounded by the broken line 82 in the RC-IGBT 100A illustrated in FIG. 1 or the RC-IGBT 100B illustrated in FIG. 2. FIG. 20 is a cross-sectional view of the IGBT region 10 taken along dashed line K-K in FIG. 19. A cross-sectional view of the IGBT region 10 taken along dashed line I-I in FIG. 19 is similar to that illustrated in FIG. 10. The RC-IGBT 107 of the seventh preferred embodiment corresponds to a combination of the RC-IGBT 102 of the second preferred embodiment and the RC-IGBT 106 of the sixth preferred embodiment.

As illustrated in FIGS. 19 and 20, a first contact hole 17 is not disposed above a region of a dummy trench gate 12 that is adjacent to a p+ type contact layer 14.

### H-2. Effects

The first contact hole 17 of an interlayer insulating film 4 is disposed above a region of the dummy trench gate 12 that is adjacent to an n+ type source layer 13, but is not disposed above a region of the dummy trench gate 12 that is adjacent to the p+ type contact layer 14. With this configuration, the following effects are also obtained in addition to the effects of the sixth preferred embodiment. That is, it is possible to increase a carrier accumulation effect by reducing the number of hole emission paths as a whole while maintaining a hole emission path in the vicinity of the n+ type source layer 13, thereby increasing a carrier density on an emitter side during energization. As a result, an on-voltage is reduced, and loss is improved.

### H-3. Modification

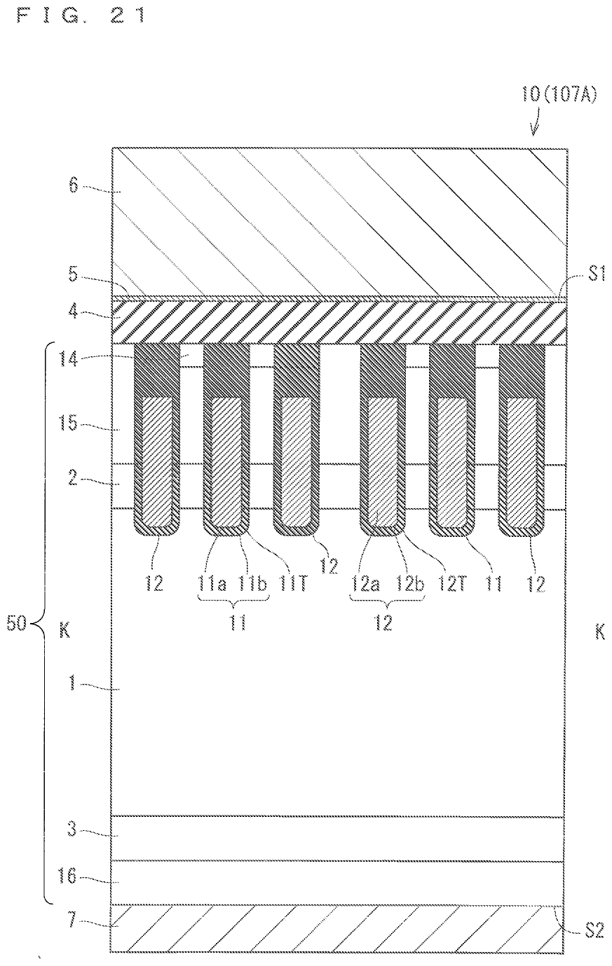

FIG. 21 is a cross-sectional view of an IGBT region 10 in an RC-IGBT 107a according to a modification of the seventh preferred embodiment taken along dashed line K-K in FIG. 19. In FIG. 20, an upper surface of a gate electrode 11a constitutes a first main surface S1 of a semiconductor substrate 50, and is higher than an upper surface of a dummy gate electrode 12a. However, as illustrated in FIG. 21, a height of an upper surface of a portion of the gate electrode 11a that is not adjacent to an n+ type source layer 13, that is, a portion of the gate electrode 11a that is adjacent to a p+ type contact layer 14 may be the same as a height of the upper surface of the dummy gate electrode 12a. By making the height of the upper surface of the portion of the gate electrode 11a that is adjacent to the p+ type contact layer 14 where no channel is formed lower than the first main surface S1 similarly to the dummy gate electrode 12a, gate capacitance can be reduced.

### I. Eighth Preferred Embodiment

### I-1. Configuration

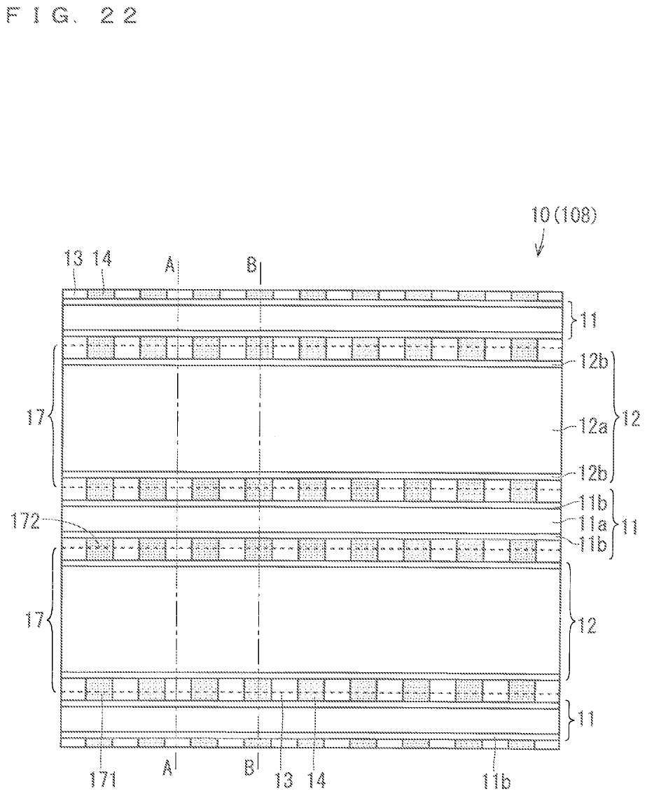

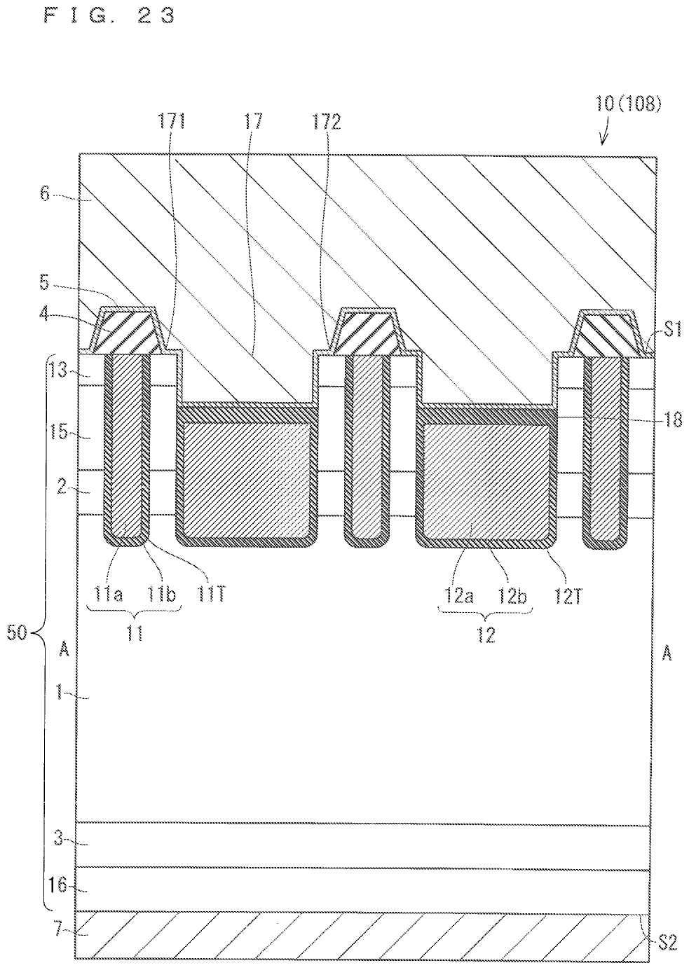

FIG. 22 is a partially enlarged plan view illustrating a configuration of an IGBT region 10 in an RC-IGBT 108 according to an eighth preferred embodiment. Either the RC-IGBT 101A illustrated in FIG. 1 or the RC-IGBT 100B illustrated in FIG. 2 is applied as the RC-IGBT 108 according to the eighth preferred embodiment. FIG. 22 is an enlarged view of a region surrounded by the broken line 82 in the RC-IGBT 100A illustrated in FIG. 1 or the RC-IGBT 100B illustrated in FIG. 2. FIG. 23 is a cross-sectional view of the IGBT region 10 taken along dashed line A-A in FIG. 22. A cross-sectional view of the IGBT region 10 taken along dashed line B-B in FIG. 22 is identical to that illustrated in FIG. 23 except for that an n+ type source layer 13 is replaced with a p+ type contact layer 14 and is therefore omitted.

### I-2. Effects

As illustrated in FIGS. 22 and 23, a width of a dummy trench gate 12 is wider than a width of an active trench gate 11. In other words, a width of a dummy trench 12T is wider than a width of a gate trench 11T. Increasing the width of the dummy trench gate 12 improves embeddability of an emitter electrode 6 embedded on the dummy trench gate 12 in the dummy trench 12T. In addition, since an interval at which the active trench gates 11 are arranged is increased, a carrier accumulation effect is enhanced.

### J. Ninth Preferred Embodiment

### J-1. Configuration

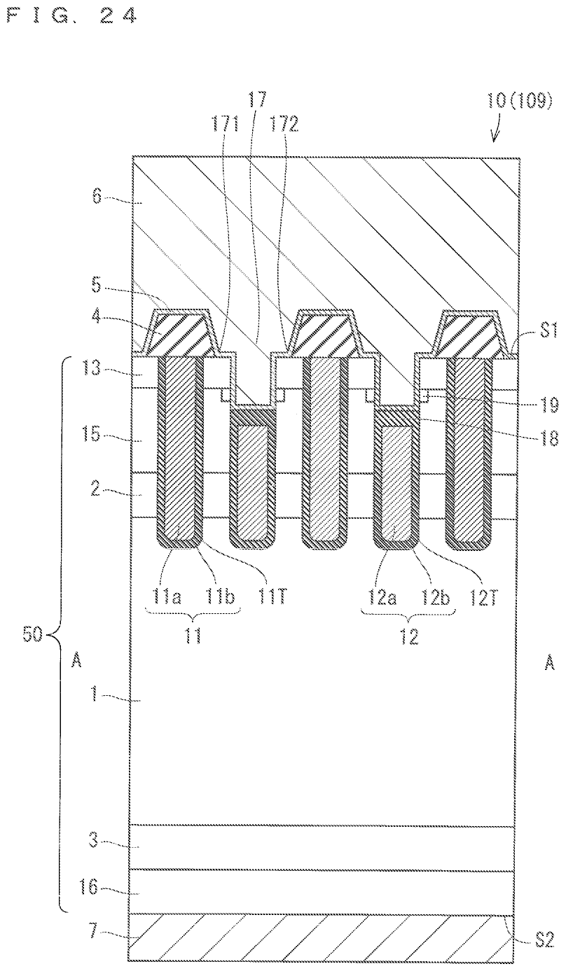

FIG. 24 is a cross-sectional view of an IGBT region 10 in an RC-IGBT 109 according to a ninth preferred embodiment. A partially enlarged plan view of the IGBT region 10 in the RC-IGBT 109 is similar to the partially enlarged plan view of the IGBT region 10 in the RC-IGBT 101 of the first preferred embodiment illustrated in FIG. 3. FIG. 24 is a cross-sectional view of the IGBT region 10 taken along dashed line A-A in FIG. 3. A cross-sectional view of the IGBT region 10 of the RC-IGBT 109 taken along dashed line B-B in FIG. 3 is identical to that illustrated in FIG. 23 except for that an n+ type source layer 13 is replaced with a p+ type contact layer 14 and is therefore omitted.

### J-2. Effects

As illustrated in FIG. 24, the RC-IGBT 109 includes a p+ type side wall contact layer 19 in a portion of a p type base layer 15 that is in contact with a side wall of a dummy trench 12T, and is similar to the RC-IGBT 101 of the first embodiment except for this. The p+ type side wall contact layer 19 reduces contact resistance between an emitter electrode 6 and the p type base layer 15 and lowers resistance of a hole discharge path, and therefore improves latch-up tolerance.

The embodiments can be freely combined and changed or omitted as appropriate.

While the disclosure has been shown and described in detail, the foregoing description is in all aspects illustrative and not restrictive. It is therefore understood that numerous modifications and variations can be devised.

What is claimed is:

1. An RC-IGBT comprising a semiconductor substrate having an IGBT region and a diode region,
wherein the semiconductor substrate includes:
an n type drift layer provided in the IGBT region and the diode region;
a p type base layer provided on the drift layer in the IGBT region; and
an n type source layer that is provided on the base layer in the IGBT region, constitutes an upper surface of the semiconductor substrate, and has a higher n type impurity concentration than the drift layer,
a plurality of gate trenches and a plurality of dummy trenches having a longitudinal direction in a first direction are provided in the semiconductor substrate in the IGBT region so as to penetrate the base layer from the upper surface of the semiconductor substrate and reach the drift layer,
the RC-IGBT further comprising:
a plurality of gate electrodes provided in the plurality of gate trenches with a gate insulating film interposed therebetween;
a plurality of dummy gate electrodes provided in the plurality of dummy trenches with a dummy gate insulating film interposed therebetween and having upper surfaces located below upper surfaces of the plurality of gate electrodes;
an interlayer insulating film provided on the upper surface of the semiconductor substrate in the IGBT region and having a first contact hole in which at least one side wall of each of the dummy trenches is exposed above a corresponding one of the dummy gate electrodes; and
an emitter electrode provided on the interlayer insulating film and in the first contact hole in the IGBT region and electrically connected to the base layer on the side wall of each of the dummy trenches exposed to the first contact hole, and
at least one dummy trench included in the plurality of dummy trenches is disposed between two gate trenches included in the plurality of gate trenches.

2. The RC-IGBT according to claim 1, further comprising a separation insulating film that is provided on each of the dummy gate electrodes and insulates each of the dummy gate electrodes from the emitter electrode,
wherein each of the dummy gate electrodes is electrically connected to each of the gate electrodes.

3. The RC-IGBT according to claim 2, wherein an upper surface of the separation insulating film is located below a lower surface of the source layer.

4. The RC-IGBT according to claim 2, wherein the separation insulating film is thicker than the gate insulating film.

5. The RC-IGBT according to claim 1, wherein each of the dummy gate electrodes is not connected to each of the gate electrodes, and is electrically connected to the emitter electrode in the first contact hole.

6. The RC-IGBT according to claim 5, wherein the upper surfaces of the dummy gate electrodes are located below a lower surface of the source layer.

7. The RC-IGBT according to claim 1, wherein both side walls of each of the dummy trenches are exposed in the first contact hole.

8. The RC-IGBT according to claim 1, wherein
two or more of the dummy trenches are disposed between two of the gate trenches, and
the interlayer insulating film covers a region between one dummy trench and another dummy trench among the two or more of the dummy trenches, the one dummy trench being adjacent to the gate trench on one side and adjacent to the other dummy trench on the other side.

9. The RC-IGBT according to claim 8, wherein the base layer is not provided between the one dummy trench adjacent to the gate trench on one side and adjacent to the other dummy trench on the other side and the other dummy trench.

10. The RC-IGBT according to claim 1, wherein
the source layer is exposed from the first contact hole in contact with the side wall of each of the dummy trenches, and
the emitter electrode is electrically connected to the source layer exposed from the first contact hole.

11. The RC-IGBT according to claim 1, wherein the dummy gate insulating film is thicker than the gate insulating film.

12. The RC-IGBT according to claim 1, wherein the source layer is intermittently disposed in the first direction.

13. The RC-IGBT according to claim 12, wherein the interlayer insulating film has the first contact hole above a region of each of the dummy trenches that is adjacent to the source layer, and does not have the first contact hole above a region of each of the dummy trenches that is not adjacent to the source layer.

14. The RC-IGBT according to claim 12, wherein an upper surface of a portion of each of the gate electrodes that is not adjacent to the source layer is at a same height as the upper surfaces of the dummy gate electrodes.

15. The RC-IGBT according to claim 13, wherein the interlayer insulating film does not have the first contact hole above a region of each of the gate trenches that is adjacent to the source layer, and has the first contact hole above a region of each of the gate trenches that is not adjacent to the source layer.

16. The RC-IGBT according to claim 1, wherein
each of the gate electrodes is connected to a first gate pad, and
each of the dummy gate electrodes is connected to a second gate pad different from the first gate pad.

17. The RC-IGBT according to claim 1, wherein a width of each of the dummy trenches is larger than a width of each of the gate trenches.

18. The RC-IGBT according to claim 1, further comprising a side wall contact layer provided in a portion of the base layer that is in contact with the side wall of each of the dummy trenches and having a higher p type impurity concentration than the base layer.

19. The RC-IGBT according to claim 1, wherein the emitter electrode is made of Al or an Al alloy, and is in direct contact with the base layer on the side wall of each of the dummy trenches exposed to the first contact hole.

20. The RC-IGBT according to claim 1, wherein
the semiconductor substrate includes:
a p type anode layer that is provided on the drift layer in the diode region and constitutes the upper surface of the semiconductor substrate;
a plurality of diode trenches penetrating the anode layer from the upper surface of the semiconductor substrate and reaching the drift layer and having a same longitudinal direction; and
a plurality of diode trench electrodes provided in the plurality of diode trenches with a diode trench insulating film interposed therebetween,
at least one of the plurality of diode trench electrodes is a first diode trench electrode having an upper surface lower than an upper surface of the anode layer,
the interlayer insulating film is provided on the upper surface of the semiconductor substrate in the diode region, and has a second contact hole in which a side wall of each of the diode trenches is exposed above the first diode trench electrode, and
the emitter electrode is provided on the interlayer insulating film and in the second contact hole in the diode-region, and is electrically connected to the anode layer on the side wall of each of the diode trenches exposed to the second contact hole.

21. The RC-IGBT according to claim 20, wherein the emitter electrode is made of Al or an Al alloy, and is in direct contact with the anode layer on the side wall of each of the diode trenches exposed to the second contact hole.

22. The RC-IGBT according to claim 20, wherein
the semiconductor substrate further includes a p type contact layer provided in a surface layer of the anode layer in the diode region and having a higher p type impurity concentration than the anode layer, and
the emitter electrode is electrically connected to the anode layer and the contact layer on the side wall of each of the diode trenches exposed to the second contact hole.

23. The RC-IGBT according to claim 22, wherein the contact layer is intermittently disposed along the longitudinal direction of the diode trenches.

24. The RC-IGBT according to claim 20, wherein the upper surface of the first diode trench electrode is at a same height as the upper surfaces of the dummy gate electrodes.
